(19) United States
(12) Patent Application Publication
(10) Pub. No.: US 2024/0164113 A1
(43) Pub. Date: May 16, 2024

(54) MEMORY STRUCTURES WITH VOIDS

(71) Applicant: Micron Technology, Inc., Boise, ID (US)

(72) Inventors: Alessandro Calderoni, Boise, ID (US); Kamal Karda, Boise, ID (US); Durai Vishak Nirmal Ramaswamy, Boise, ID (US)

(21) Appl. No.: 18/510,464

(22) Filed: Nov. 15, 2023

Related U.S. Application Data
(60) Provisional application No. 63/425,967, filed on Nov. 16, 2022.

(51) Int. Cl. H10B 53/20; G11C 5/06; H01L 21/28; H01L 29/51; H01L 29/66; H01L 29/78; H10B 51/10; H10B 51/20; H10B 53/10

(52) U.S. Cl. CPC H10B 53/20; G11C 5/063; H01L 29/40111; H01L 29/516; H01L 29/6684; H01L 29/78391; H10B 51/10; H10B 51/20; H10B 53/10

(57) ABSTRACT

Methods, systems, and devices for memory structures with voids are described. A memory architecture may include voids between adjacent columns of memory cells. For example, a memory array may be manufactured by forming one or more sacrificial structures, as well as a liner material on sidewalls of the sacrificial structures, extending in the column direction. Memory cells may be formed on the sacrificial structures by patterning a conductive material to form bottom electrodes, forming a ferroelectric material adjacent to the bottom electrodes, and forming a set of plate lines over the ferroelectric material. The sacrificial structures may then be removed to form voids between at least some adjacent columns of memory cells.

### CROSS REFERENCE

The present Application for Patent claims priority to U.S. Patent Application Ser. No. 63/425,967 by Calderoni et al., entitled “MEMORY STRUCTURES WITH VOIDS,” filed Nov. 16, 2022, which is assigned to the assignee hereof, and which is expressly incorporated by reference in its entirely herein.

### FIELD OF TECHNOLOGY

The following relates to one or more systems for memory, including memory structures with voids.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, a component may read (e.g., sense, detect, retrieve, identify, determine, evaluate) a stored state in the memory device. To store information, a component may write (e.g., program, set, assign) the state in the memory device.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source. FeRAM may be able to achieve densities similar to volatile memory but may have non-volatile properties due to the use of a ferroelectric capacitor as a storage device.

### BRIEF DESCRIPTION OF THE DRAWINGS

FIGS. 1 through 1B-1 illustrate examples of processing steps of a method that supports memory structures with voids in accordance with examples as disclosed herein.

FIGS. 2 through 2B illustrate examples of processing steps of a method that supports memory structures with voids in accordance with examples as disclosed herein.

FIGS. 3 through 3B illustrate examples of processing steps of a method that supports memory structures with voids in accordance with examples as disclosed herein.

FIGS. 4 through 4B illustrate examples of processing steps of a method that supports memory structures with voids in accordance with examples as disclosed herein.

FIGS. 5 through 5B illustrate examples of processing steps of a method that supports memory structures with voids in accordance with examples as disclosed herein.

FIGS. 6 through 6B illustrate examples of processing steps of a method that supports memory structures with voids in accordance with examples as disclosed herein.

FIGS. 7 through 7B illustrate examples of processing steps of a method that supports memory structures with voids in accordance with examples as disclosed herein.

FIGS. 8 through 8B illustrate examples of processing steps of a method that supports memory structures with voids in accordance with examples as disclosed herein.

FIGS. 9 through 9B illustrate examples of processing steps of a method that supports memory structures with voids in accordance with examples as disclosed herein.

FIGS. 10 through 10B illustrate examples of processing steps of a method that supports memory structures with voids in accordance with examples as disclosed herein.

FIGS. 11 through 11C illustrate examples of processing steps of a method that supports memory structures with voids in accordance with examples as disclosed herein.

FIGS. 12 through 12B illustrate examples of processing steps of a method that supports memory structures with voids in accordance with examples as disclosed herein.

FIGS. 13 through 13B illustrate examples of processing steps of a method that supports memory structures with voids in accordance with examples as disclosed herein.

FIGS. 14 through 14B illustrate examples of processing steps of a method that supports memory structures with voids in accordance with examples as disclosed herein.

FIGS. 15 through 15B illustrate examples of processing steps of a method that supports memory structures with voids in accordance with examples as disclosed herein.

FIGS. 16 through 16B illustrate examples of processing steps of a method that supports memory structures with voids in accordance with examples as disclosed herein.

FIGS. 17 through 17E illustrate examples of processing steps of a method that supports memory structures with voids in accordance with examples as disclosed herein.

FIGS. 18 through 18B illustrate examples of processing steps of a method that supports memory structures with voids in accordance with examples as disclosed herein.

FIGS. 19 through 19B illustrate examples of processing steps of a method that supports memory structures with voids in accordance with examples as disclosed herein.

FIGS. 20 through 20B illustrate examples of processing steps of a method that supports memory structures with voids in accordance with examples as disclosed herein.

FIGS. 21 through 21B illustrate examples of processing steps of a method that supports memory structures with voids in accordance with examples as disclosed herein.

FIG. 22 illustrates an example of a schematic diagram of an example memory array comprising ferroelectric capacitors which supports memory structures with voids in accordance with examples as disclosed herein.

FIG. 23 illustrates an example of a schematic diagram of another example memory array comprising ferroelectric capacitors which supports memory structures with voids in accordance with examples as disclosed herein.

FIG. 24 shows a flowchart illustrating a method or methods that support memory structures with voids in accordance with examples as disclosed herein.

FIG. 25 shows a flowchart illustrating a method or methods that support memory structures with voids in accordance with examples as disclosed herein.

### DETAILED DESCRIPTION

In some memory architectures, such as ferroelectric random access memory (FeRAM) and hybrid FeRAM architectures, a memory cell may include a capacitor that includes a ferroelectric material to store a charge, or a polarization, or both, representative of a programmable logic state. The memory cells may be arranged in a grid structure having one or more rows and one or more columns of memory cells. Each memory cell of a column may be coupled with a same digit line (e.g., a bit line) and plate line, while each memory cell of a row may be coupled with a same word line. In some cases, memory cells of adjacent columns may have a relatively large capacitance between plates of the memory cells, for example, based on dielectric materials supporting the array or a dielectric constant of the logic storage components of the memory cells, among other factors. It may be beneficial to reduce the capacitance between plates, for example, to improve efficiency of memory operations.

As described herein, a memory architecture may include voids between adjacent columns of memory cells, which may reduce a capacitance between electrodes of the memory cells. For example, a memory array may be manufactured by forming one or more sacrificial structures, as well as a liner material on sidewalls of the sacrificial structures, extending in the column direction. Memory cells may be formed on the sacrificial structures by patterning a conductive material to form bottom electrodes, forming a ferroelectric material adjacent to the bottom electrodes, and forming a set of plate lines (e.g., top electrodes) over the ferroelectric material. The sacrificial structures may then be removed, for example using a selective wet etch or wet exhume process, to form voids between at least some adjacent columns of memory cells. The voids may include a substance, which may be fluid, such as air. This substance (e.g., fluid such as air) may have a relatively low dielectric constant (as compared with other materials) to reduce a capacitance between electrode and may reduce (e.g., eliminate) undesirable coupling between electrodes during memory operations.

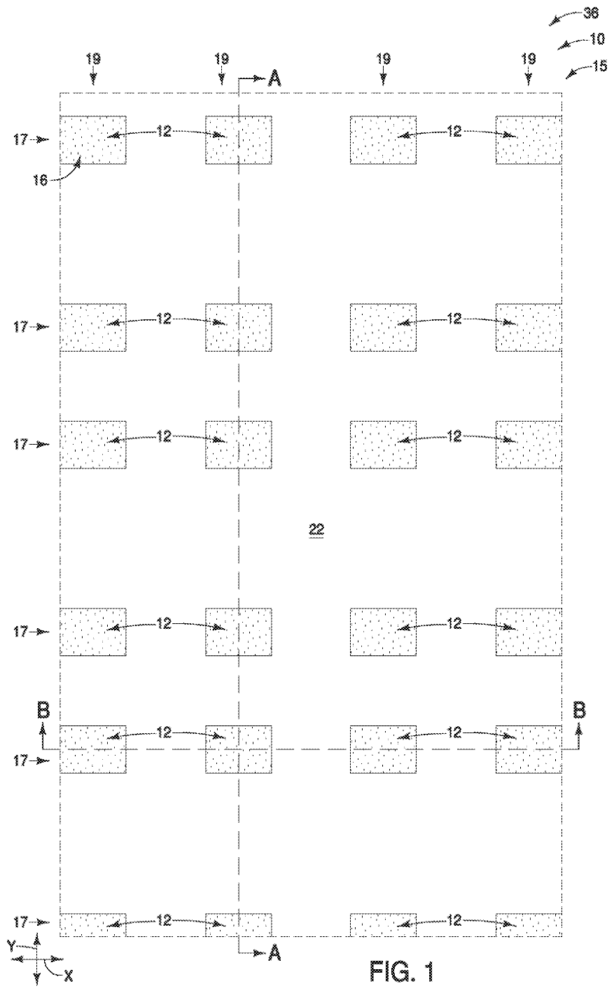

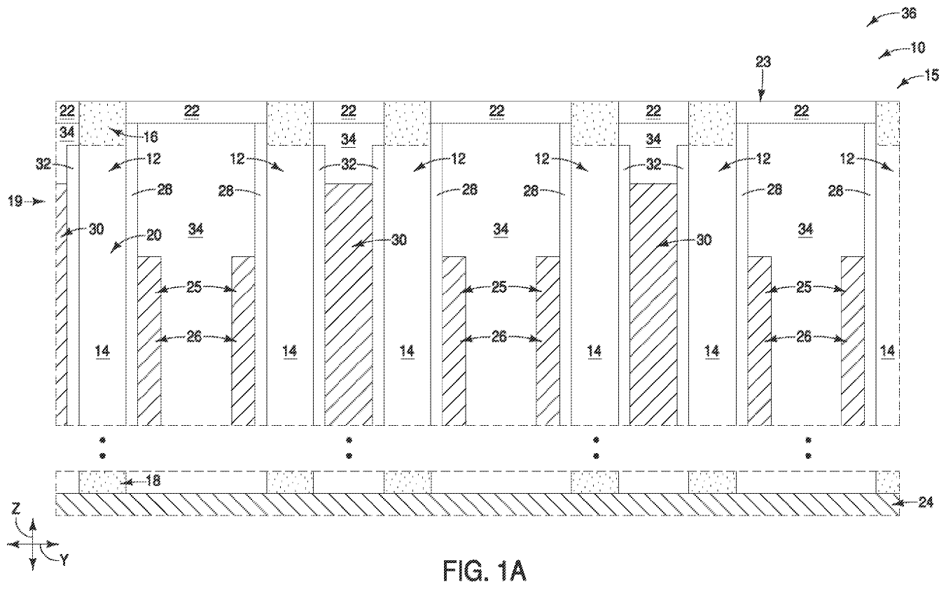

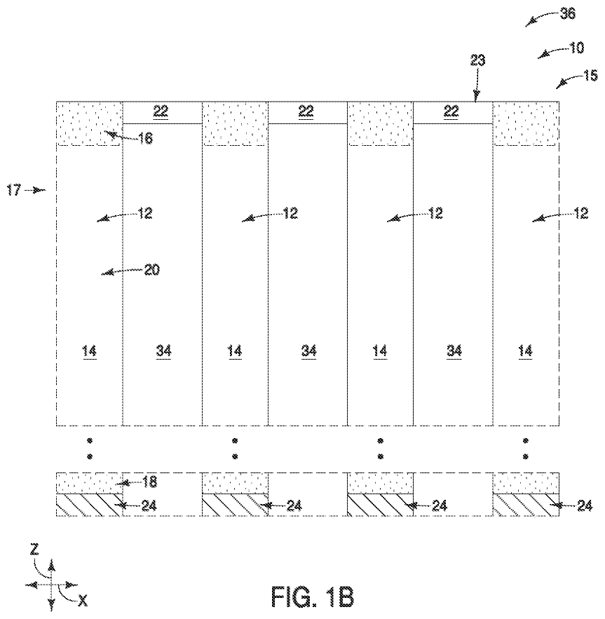

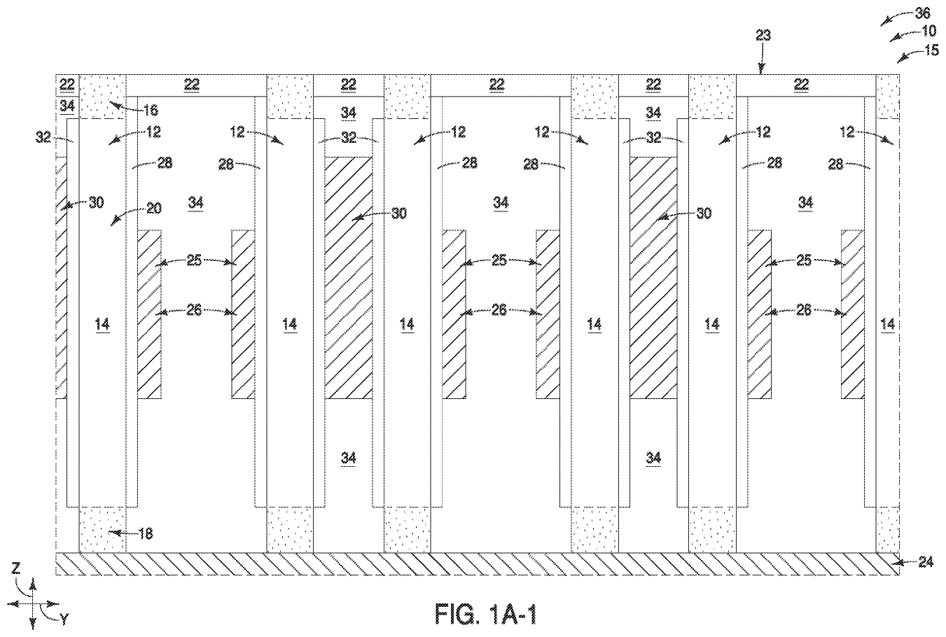

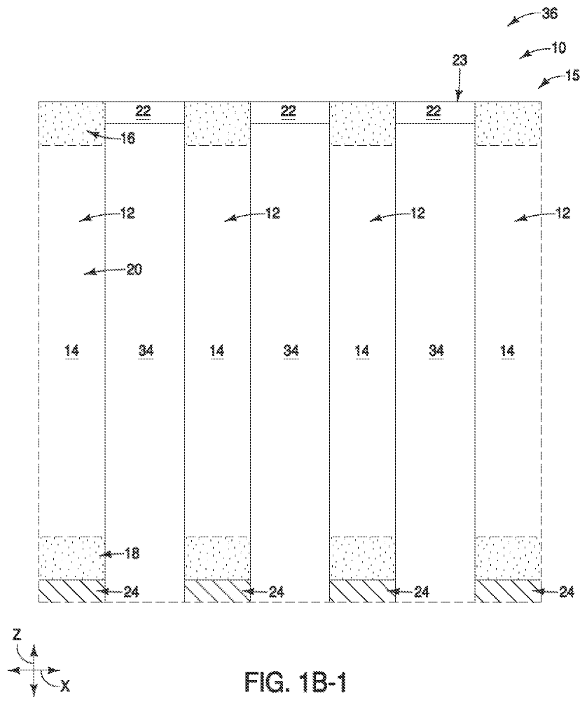

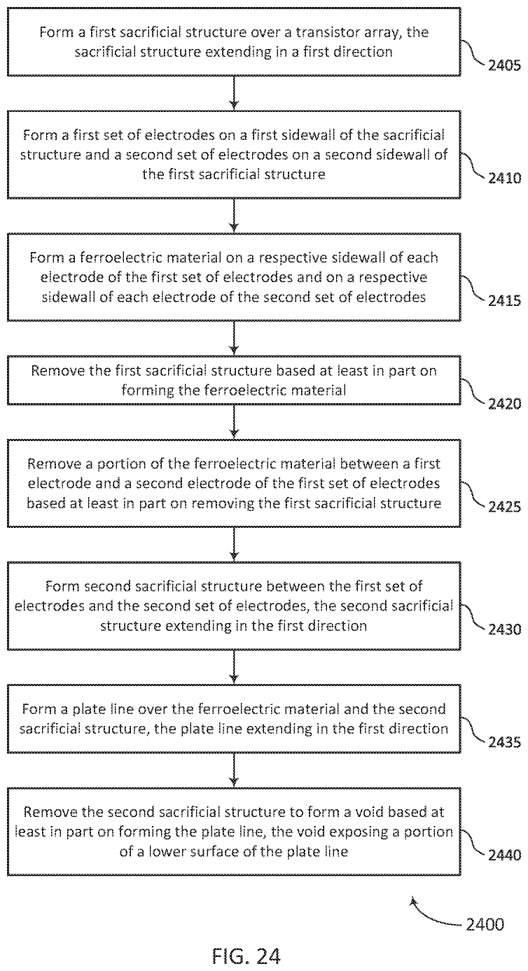

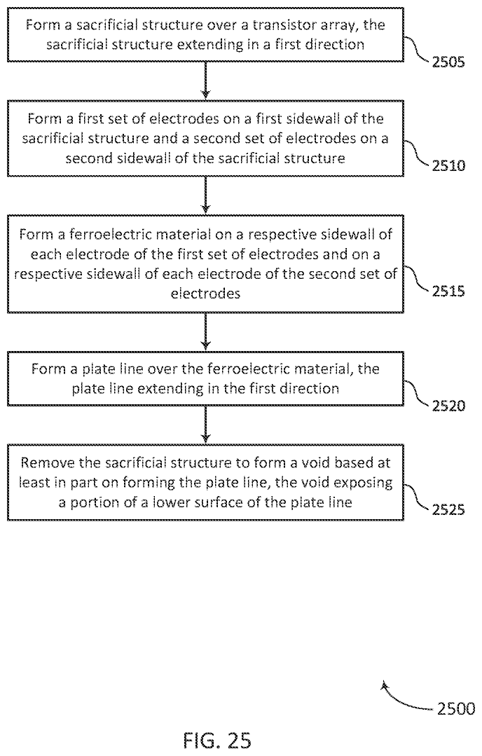

Features of the disclosure are described in the context of processing steps of a method and schematics of example memory arrays with reference to FIGS. 1 through 23. These and other features of the disclosure are further illustrated by and described with reference to flowcharts that relate to memory structures with voids as described with reference to FIGS. 24 and 25.

Some embodiments include methods of forming memory architecture (e.g., FeRAM, etc.) in which bottom electrodes are configured as angle plates (e.g., “L-shaped” plates) having vertically-extending segments (e.g., legs) joining to horizontally-extending segments (e.g., legs). The angle plates may be supported by insulative structures (rails) during manufacturing that extend along the angle plates and are adjacent to the vertically-extending legs. The insulative structures may extend along a same direction as digit lines (e.g., a column direction). Capacitor-insulative-material (e.g., ferroelectric-insulative-material) may be along the bottom electrodes. Leaker-device-structures may be provided to extend between the bottom electrodes and top electrode material. One or more slits may pass through the top electrode material and may be aligned with the insulative structures to pattern the top electrode material into two or more plates. Voltage of the individual plates may be controlled. during various operations associated with a memory array (e.g., READ/WRITE operations). The insulative structures may be removed, for example after forming the plates, which may reduce capacitance between memory cells of adjacent columns. Example embodiments are described with reference to FIGS. 1-21B.

Referring to FIGS. 1-1B, a construction 10 includes vertically-extending pillars 12. The pillars 12 comprise semiconductor material 14. The pillars 12 are all substantially identical to one another, with the term “substantially identical” meaning identical to within reasonable tolerances of fabrication and measurement.

The semiconductor material 14 may comprise any suitable composition(s), and in some embodiments may comprise, consist essentially of, or consist of one or more of silicon, germanium, III/V semiconductor material (e.g., gallium phosphide), semiconductor oxide, etc.; with the term MN semiconductor material referring to semiconductor materials comprising elements selected from groups III and V of the periodic table (with groups III and V being old nomenclature, and now being referred to as groups 13 and 15). In some embodiments, the semiconductor material 14 may comprise, consist essentially of, or consist of appropriately-doped silicon. The silicon may be in any suitable form, and in some embodiments may be monocrystalline, polycrystalline and/or amorphous.

Each of the pillars 12 includes a channel region 20 between an upper source/drain region 16 and a lower source/drain region 18. Stippling is utilized in the drawings to indicate that the source/drain regions 16 and 18 are heavily doped. In some embodiments, the source/drain regions 16 and 18 may be n-type doped by incorporating one or both of phosphorus and arsenic into the semiconductor material (e.g., silicon) 14 of the pillars 12. In some embodiments, one or both of the source/drain regions 16 and 18 may comprise additional conductive material besides the conductively-doped semiconductor material 14. For instance, one or both of the source/drain regions 16 and 18 may include metal silicide (e.g., titanium silicide, tungsten silicide, etc.) arid/or other suitable conductive materials (e.g., titanium, tungsten, etc.). In some embodiments, the pillars 12 may be considered to be capped by the upper source/drain regions 16, with the term “capped” indicating that the upper source/drain regions may or may not include the semiconductor material 14 of the pillars 12.

The pillars 12 may be considered to be arranged in an array 15. The array may be considered to comprise rows 17 extending along an indicated x-axis direction, and to comprise columns 19 extending along an indicated y-axis direction.

Insulative material 22 extends between the upper source/drain regions 16. The insulative material 22 may comprise any suitable composition(s); and in some embodiments may comprise, consist essentially of, or consist of silicon nitride, silicon dioxide, aluminum oxide, etc. In some embodiments, the insulative material 22 may be referred to as a first insulative material.

A planarized upper surface 23 extends across the insulative material 22 and the source/drain regions 16. The planarized surface 23 may be formed utilizing chemical-mechanical polishing (CMP) and/or any other suitable process(es). In some embodiments, the surface 23 may be referred to as an upper surface of the construction 10.

The construction includes conductive structures (digit lines) 24 under the pillars 12. The digit lines 24 extend along the column direction (the illustrated y-axis direction) and are electrically coupled with the lower source/drain regions 18 of the pillars. The digit lines may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.).

In the illustrated embodiment, the digit lines are physically against the lower source/drain regions 18. In some embodiments, the digit lines may comprise metal (e.g., titanium, tungsten, etc.), the source/drain regions 18 may comprise conductively-doped silicon, and metal silicide may be present where the silicon of the source/drain regions 18 interfaces with the digit lines 24.

Gating structures e.g., word lines 25 are alongside the pillars 12 and comprise gates 26. The gates 26 are spaced from the pillars by dielectric material (also referred to as gate dielectric material) 28. The gating structures 25 extend along the row direction (i.e., along the illustrated x-axis direction), and thus extend in and out of the page relative to the cross-sectional view of FIG. 1A.

The gating structures 25 (and associated gates 26) may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.).

The dielectric material 28 may comprise any suitable composition(s); and in some embodiments may comprise, consist essentially of, or consist of one or more of silicon nitride, silicon dioxide, aluminum oxide, hafnium oxide, etc.

The dielectric material 28 is provided between the gates 26 and the channel regions 20, and may extend to any suitable vertical dimension. In the shown embodiment the dielectric material 28 extends upwardly beyond the uppermost surfaces of the gates 26. In other embodiments the dielectric material 28 may or may not extend vertically beyond the gates 26.

The gates (transistor gates) 26 may be considered to be operatively adjacent to (operatively proximate to) the channel regions 20 such that a sufficient voltage applied to an individual gate 26 (specifically along a word line 25 comprising the gate) will induce an electric field on a channel region near the gate which enables current flow through the channel region to electrically couple the source/drain regions on opposing sides of the channel region with one another. If the voltage to the gate is below a threshold level, the current will not flow through the channel region, and the source/drain regions on opposing sides of the channel region will not be electrically coupled with one another. The selective control of the coupling/decoupling of the source/drain regions through the level of voltage applied to the gate may be referred to as gated coupling of the source/drain regions.

Shield lines 30 are alongside the pillars 12, and are spaced from the pillars by dielectric material 32. The shield lines may be electrically coupled with ground or any other suitable reference voltage. The shield lines 30 extend along the row direction (i.e., along the illustrated x-axis direction). The shield lines 30 may be considered to be within regions between the pillars 12 along the cross-sectional view of FIG. 1A.

The dielectric material 32 may comprise any suitable composition(s); and in some embodiments may comprise, consist essentially of, or consist of one or more of silicon dioxide, silicon nitride, aluminum oxide, hafnium oxide, etc. In the shown embodiment the dielectric material 32 extends vertically beyond the shield lines 30. In other embodiments the dielectric material 32 may or may not extend vertically beyond the shield lines 30. The shield lines 30 may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.).

In the shown embodiment, each of the pillars 12 shown along the cross-section of FIG. 1A has one side adjacent a gate 26, and has an opposing side adjacent a shield line 30.

In the shown embodiment, insulative material 34 is over the gates 26 and the shield lines 30. The insulative material 34 may comprise any suitable composition(s); and may, for example, comprise silicon dioxide, silicon nitride, aluminum oxide, etc. In some embodiments the material 34 may comprise a same composition as one or both of the dielectric materials 28 and 32, and in other embodiments the material 34 may comprise a different composition than at least one of the dielectric materials 28 and 32.

The construction 10 may be supported by a semiconductor base (not shown). The base may comprise semiconductor material; and may, for example, comprise, consist essentially of, or consist of monocrystalline silicon. The base may be referred to as a semiconductor substrate. The term “semiconductor substrate” means any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductor substrates described above. In some applications, the base may correspond to a semiconductor substrate containing one or more materials associated with integrated circuit fabrication. Such materials may include, for example, one or more of refractory metal materials, barrier materials, diffusion materials, insulator materials, etc.

in some embodiments, the construction 10 of FIGS. 1-1B may be considered to represent a portion of an integrated assembly 36.

In the embodiment of FIGS. 1A and 1B, a gap is provided within the construction 10 to break a region of the pillars 12 above the lower source/drain regions 18. The gap enables the view of construction 10 to be collapsed into a smaller area, which leaves more room for additional materials formed over the construction 10 at subsequent process stages. It is to be understood that the pillars 12 extend across the illustrated gap. FIGS. 1A-1 and 1B-1 show views along the same cross-sections as FIG. 1A and FIG. 1B, and show the construction 10 without the gap of FIGS. 1A and 1B. FIGS. 1A-1 and 1B-1 are provided to assist the reader in understanding the arrangement of construction 10. The views of FIGS. 1A and 1B (i.e., the views with the gaps in construction 10) will be used for the remaining figures of this disclosure.

In some examples, the construction 10 may represent a transistor array, in which each pillar 12 may be an example of a transistor of the array. The transistor array may include a set of transistors arranged in one or more columns extending in the y-direction and one or more rows extending in the x-direction. Each transistor may include a contact, such as a respective source/drain region, 16, exposed on the surface of the transistor array.

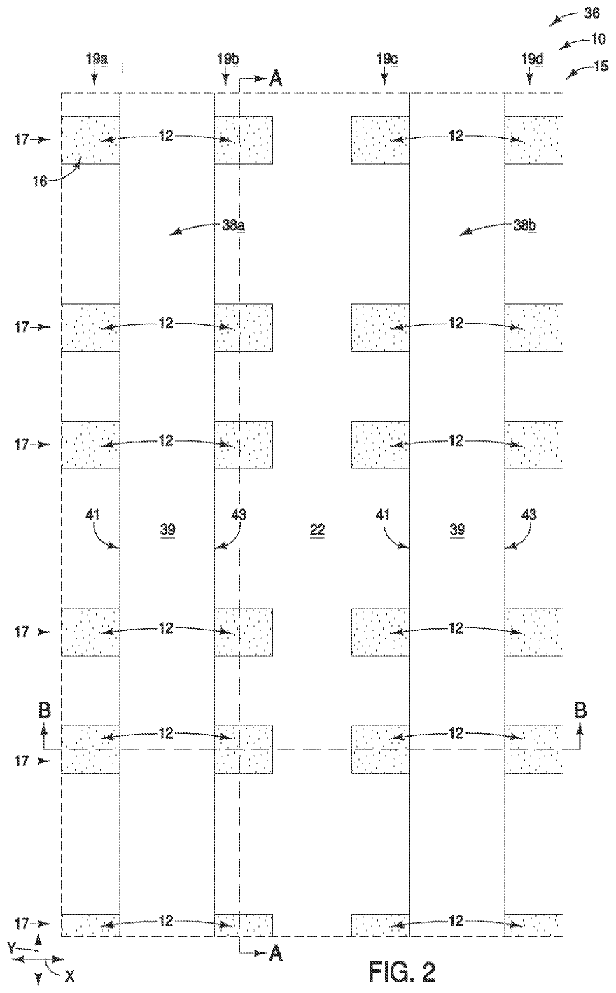

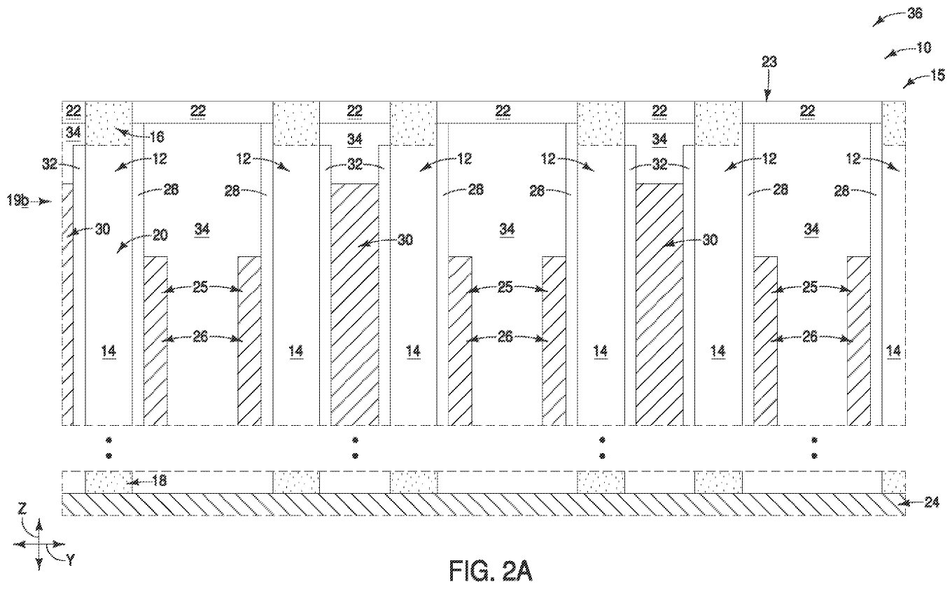

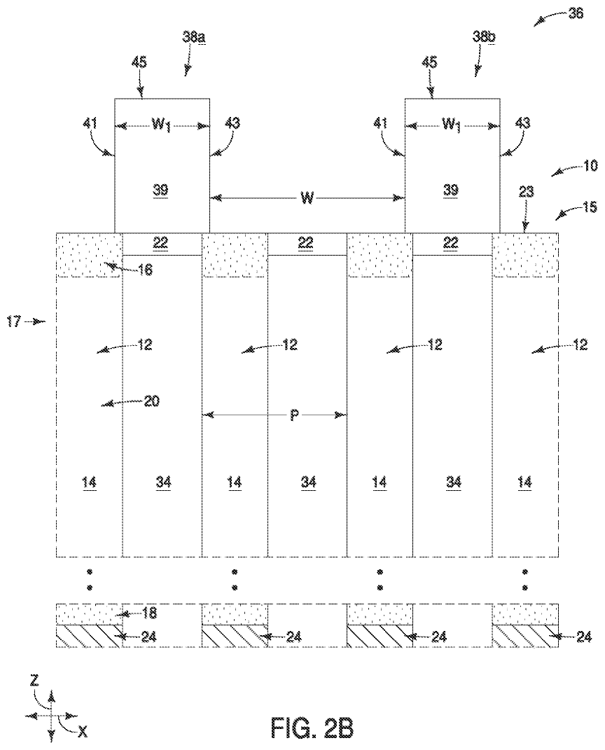

Referring to FIGS. 2-2B, the assembly 36 is shown at a process stage subsequent to that of FIGS. 1-1B. Linear insulative structures (rails, beams) 38, which may be examples of sacrificial structures, are formed over the upper surface 23 of construction 10. The structures 38 comprise sacrificial material 39. The material 39 may comprise any suitable composition(s); and in some embodiments may comprise, consist essentially of, or consist of silicon (e.g., amorphous silicon and/or polycrystalline silicon), low-density silicon dioxide, carbon, etc.

The illustrated linear structures 38 are labeled 38a and 38b so that they may be distinguished relative to one another.

The linear structures 38 extend along the column direction (the illustrated y-axis direction), and are formed to be between columns of the pillars 12. Each of the linear structures 38 has a pair of opposing lateral surfaces 41 and 43. The surfaces 41 and 43 may be referred to as first and second lateral sides, respectively, of the linear structures 38. Each of the linear structures also has a top surface 45.

Each of the linear structures 38 may be considered to be associated with a pair of the columns 19 of the pillars 12, with such associated columns being along the sides 41 and 43. For instance, the columns 19 of FIG. 2 are labeled as 19a-d. Columns 19a and 19b are along the sides 41 and 43 of the linear structure 38a and may be considered to be associated with such linear structure. Similarly, columns 19c and 19d are along the sides 41 and 43 of the linear structure 38b and may be considered to be associated with such linear structure.

In the shown embodiment, the linear structures 38 laterally overlap portions of the source/drain. regions 16 of the associated columns 19, as shown in FIG. 2B. In other embodiments, the linear structures 38 may be formed between the associated columns and may not laterally overlap the source/drain regions 16 of the associated columns.

The linear structures 38 may be formed with any suitable processing. For instance, an expanse of the material 39 may be formed (e.g., deposited) across the upper surface 23, and such expanse may be patterned (e.g., etched) utilizing a patterned mask (not shown) and one or more suitable etches. In some examples, etching the material 39 may form a set of trenches extending parallel to the linear structures 38. In some cases, each trench may expose a respective portion of the surface of the transistor array.

In the illustrated embodiment, the sidewall surfaces (sidewalls) 41 and 43 are substantially vertical and extend substantially orthogonally relative to the substantially horizontal upper surface 23. The term “substantially vertical” means vertical to within reasonable tolerances of fabrication and measurement, the term “substantially orthogonal” means orthogonal to within reasonable tolerances of fabrication and measurement, and the term “substantially horizontal” means horizontal to within reasonable tolerances of fabrication and measurement.

FIG. 2B shows the pillars 12 to be on a pitch P along the cross-section of the figure. The linear structures 38a and 38b are spaced from one another by a gap having width W. The linear structures 38a and 38b have widths W₁ along the cross-section of FIG. 2B. The widths W₁ may be any suitable dimension, and in some embodiments may be within a range of from about one-fourth of the pitch P to about three-fourths of the pitch P. In some embodiments, the widths W₁ may be within a range of from about 15 nm to about 40 nm. The width W may be any suitable dimension, and in some embodiments may be within a range of from about 20 nanometers (nm) to about 60 nm, within a range of from about 20 nm to about 100 nm, etc.

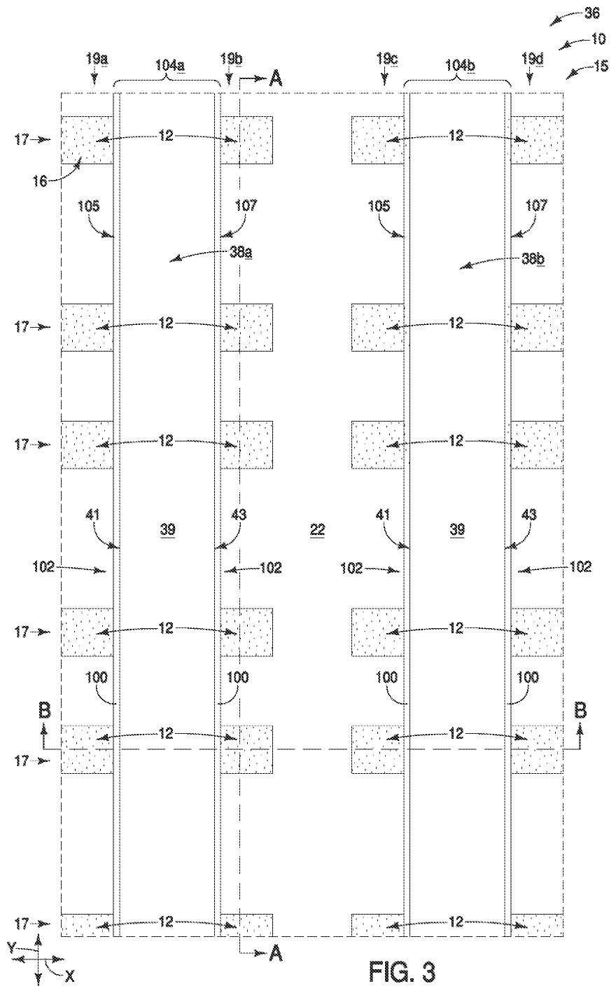

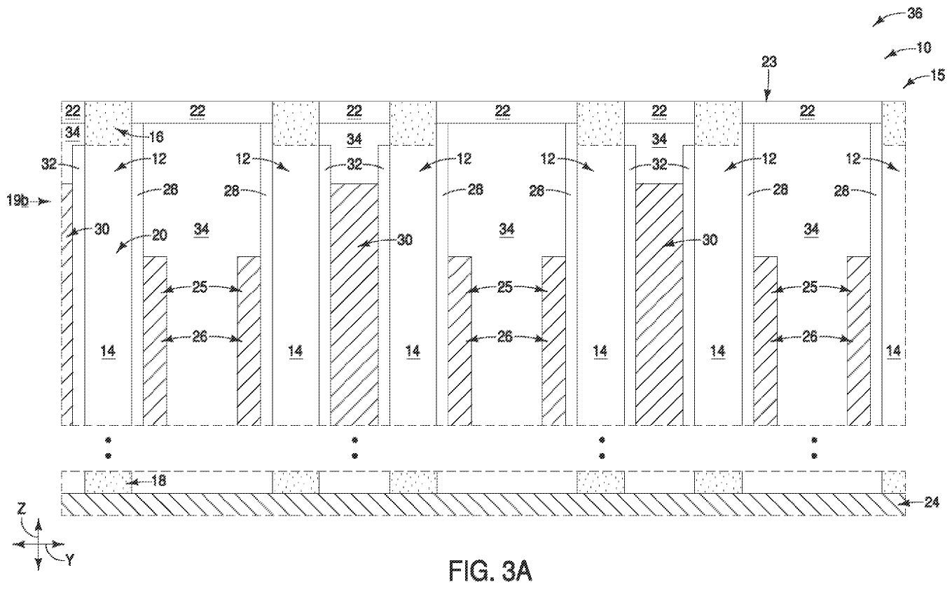

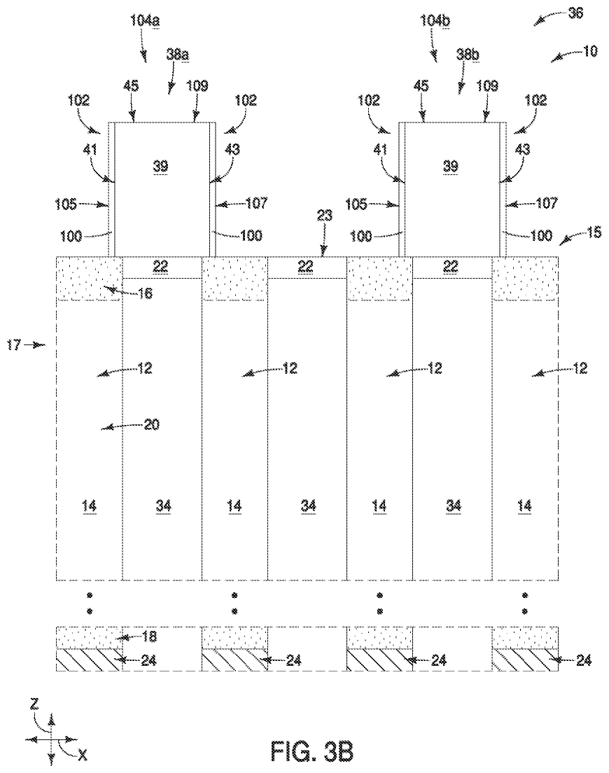

Referring to FIGS. 3-3B, protective material 100 is formed along the sidewall surfaces 41 and 43 of the sacrificial material 39. In some embodiments, the protective material 100 may be referred to as “other” material, to indicate that it is other material relative to the sacrificial material 39, such as a second oxide material different from the oxide material of the sacrificial material 39. Additionally or alternatively, the protective material 100 may be deposited to form one or more liner structures. For example, the protective material 100 may be deposited to form a first liner structure on the sidewall 41 and a second liner structure on the sidewall 43.

The protective material 100 may comprise any suitable composition(s), including, for example, one or more of silicon nitride, aluminum oxide, hafnium oxide, zirconium oxide, etc. The protective material 100 may be formed to any suitable lateral thickness along the sidewalls 41 and 41, and in some embodiments such lateral thickness may be within a range of from about 1 nm to about 4 nm.

The protective material 100 may is configured as spacers (liners) 102 along the sidewall surfaces 41 and 43. Such spacers may be formed with any suitable processing. For instance, a layer of material 100 may be formed over an upper surface of the assembly 36 and then such layer may be patterned with an anisotropic etch to form the spacers 102. The structures 38a and 38b, and spacers 102. together form linear structures 104a and 104b. The linear structures 104a and 104b have outer sidewalls (sidewall surfaces) 105 and 107 along the spacers 102, and have top surfaces 109 extending across the materials 39 and 100.

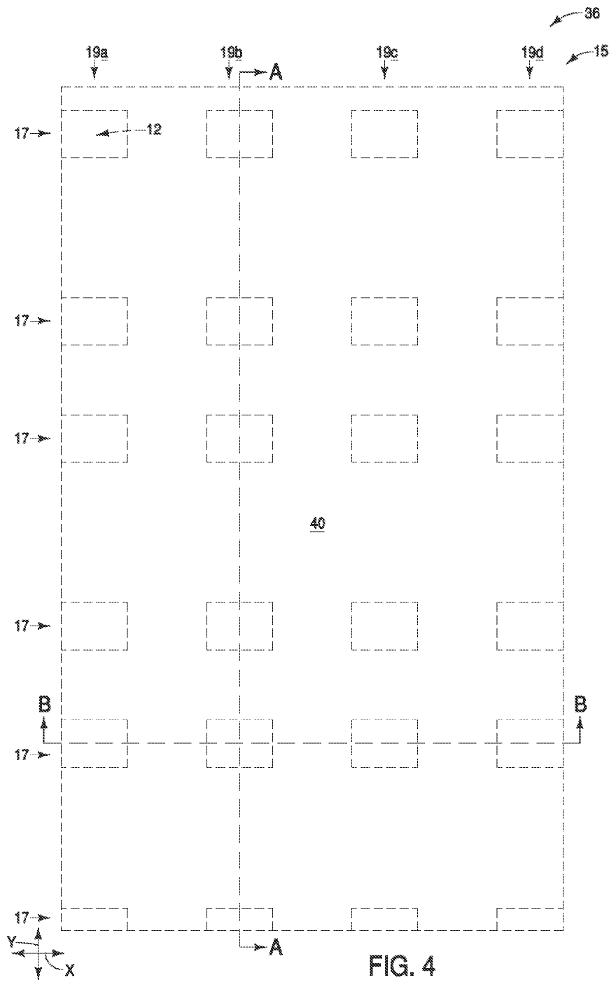

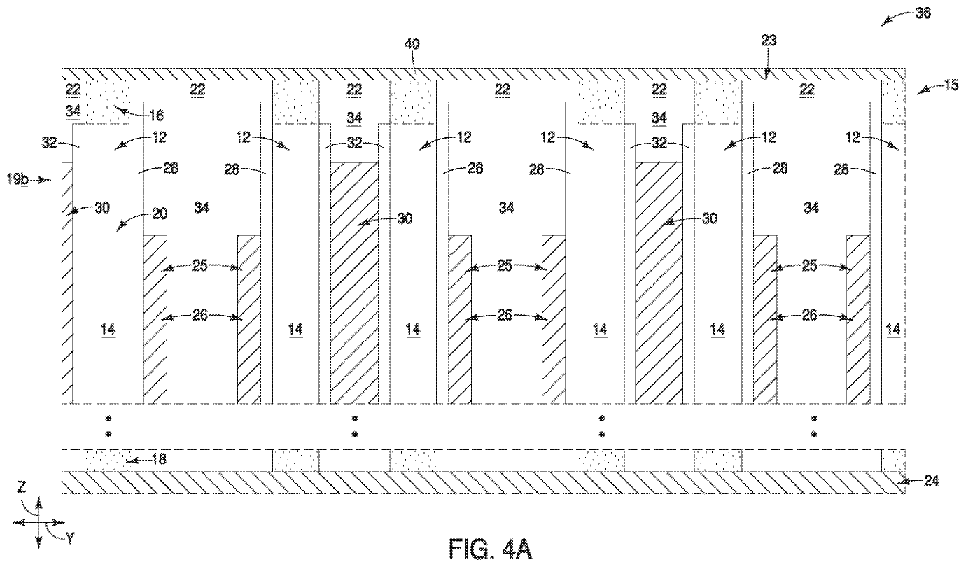

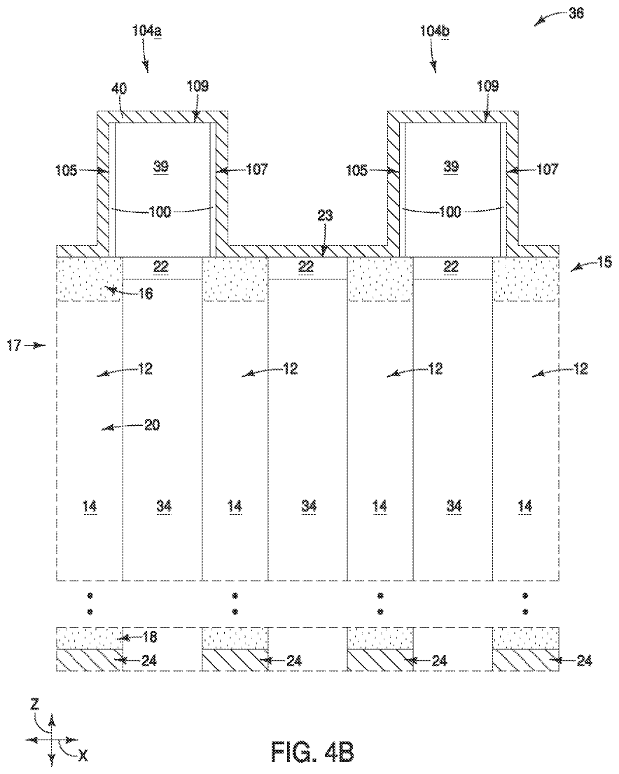

Referring to FIGS. 4-4B, bottom-electrode-material 40 is formed to extend conformity along the linear structures 104, and along regions of the upper surface 23 between the linear structures. For example, the bottom-electrode-material 40 may be deposited on sidewalls of the linear structures 104 (e.g., on sidewalls of the liner structures on the sidewall surfaces 41 and 43) and on exposed portions of the surface of the transistor array. The bottom-electrode-material 40 extends across the upper source/drain regions 16, and is electrically coupled with such source/drain regions (e.g., electrically coupled with contacts of transistors of the transistor array). In the illustrated embodiment, the bottom-electrode-material 40 is directly against upper surfaces of the source/drain regions 16. The bottom-electrode-material 40 may have any suitable thickness. In some embodiments, the material 40 may have a thickness within a range of from about 1 nm to about 5 nm. The source/drain regions 16 and associated pillars 12 are shown in dashed-line (phantom) view in FIG. 4 to indicate that they are under other materials.

The bottom-electrode-material 40 may comprise any suitable electrically conductive composition(s); such as, for example, one or more of various metals titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.). In some embodiments, the bottom-electrode-material 40 may comprise, consist essentially of, or consist of titanium nitride.

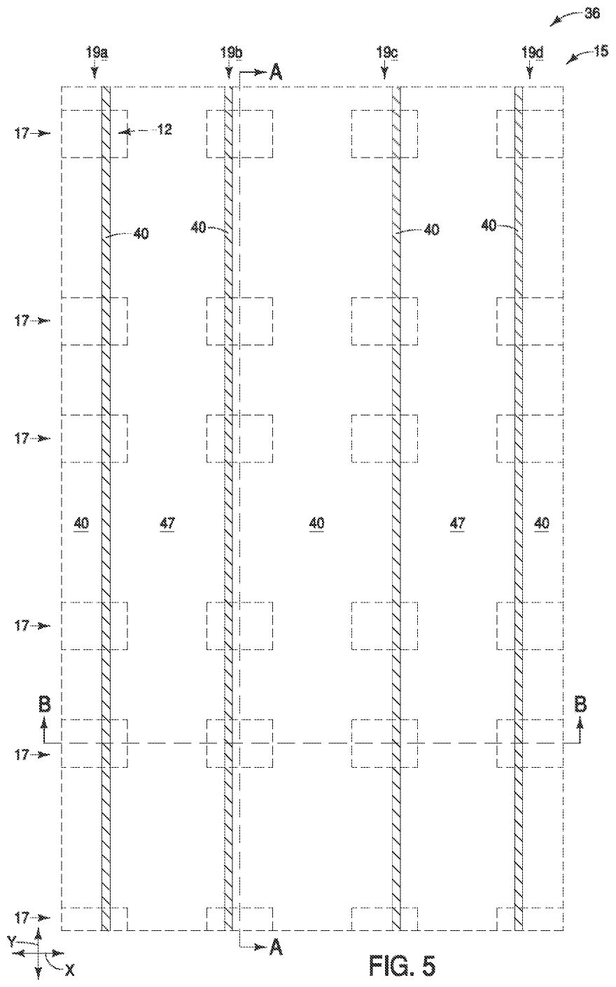

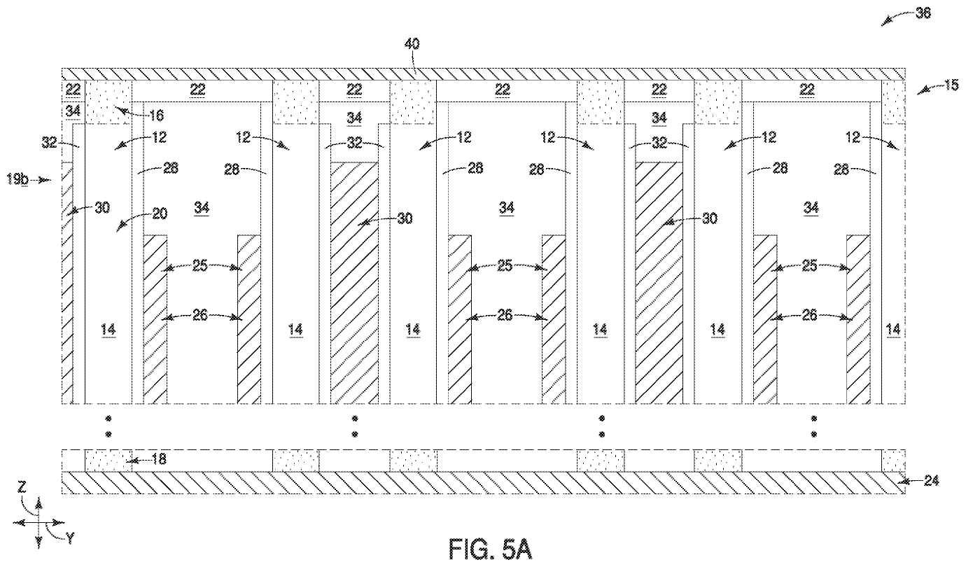

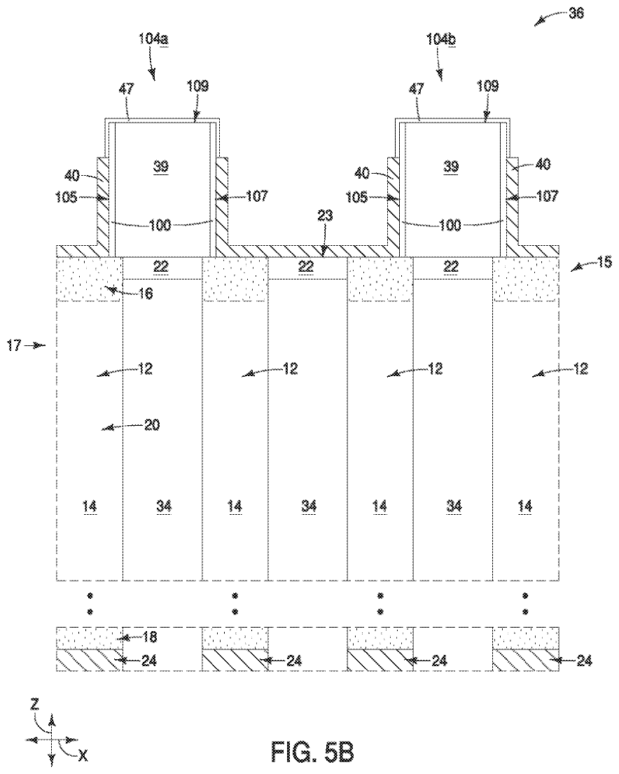

Referring to FIGS. 5-5B, the bottom electrode material 40 is etched back from upper portions of the linear structures 104 to expose upper portions of the linear structures (bottom portions of the bottom electrode material may be protected with suitable material (not shown) during such etch-back). Subsequently, leaker-device-material 47 is formed along the top surfaces 109 and sidewall surfaces 105/107 of the exposed upper portions of the linear structures 104. The leaker-device-material 47 may be, for example, deposited over an entirety of the upper surface of the assembly 36 and then patterned to remain only along the upper portions of the linear structures 104.

The leaker-device-material 47 may comprise any suitable composition or combination of compositions. In some embodiments, the leaker-device-material 47 may comprise, consist essentially of, or consist of one or more of titanium, nickel and niobium in combination with one or more of germanium, silicon, oxygen, nitrogen and carbon. In some embodiments, the leaker device material may comprise, consist essentially of, or consist of one or more of Si, Ge, SiN, TiSiN, TiO, TiN, NiO, NiON and TiON, where the chemical formulas indicate primary constituents rather than particular stoichiometries. In some embodiments, the leaker-device-material may comprise, consist essentially of, or consist of titanium, oxygen and nitrogen. In some embodiments, the leaker-device-material may comprise amorphous silicon, niobium monoxide, silicon-rich silicon nitride, etc., either alone or in any suitable combination.

In some embodiments, the leaker-device-material 47 may be a continuous layer having a thickness within a range of from about 2 angstroms (Å) to about 20 Å. In some embodiments, the leaker-device-material may be a continuous layer having a thickness within a range of from about 6 Å to about 15 Å.

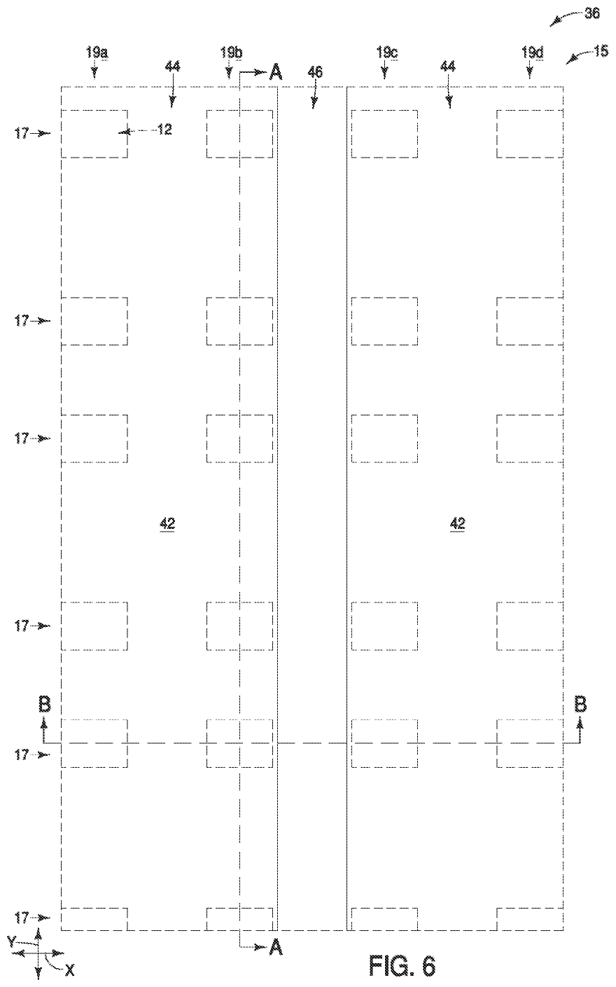

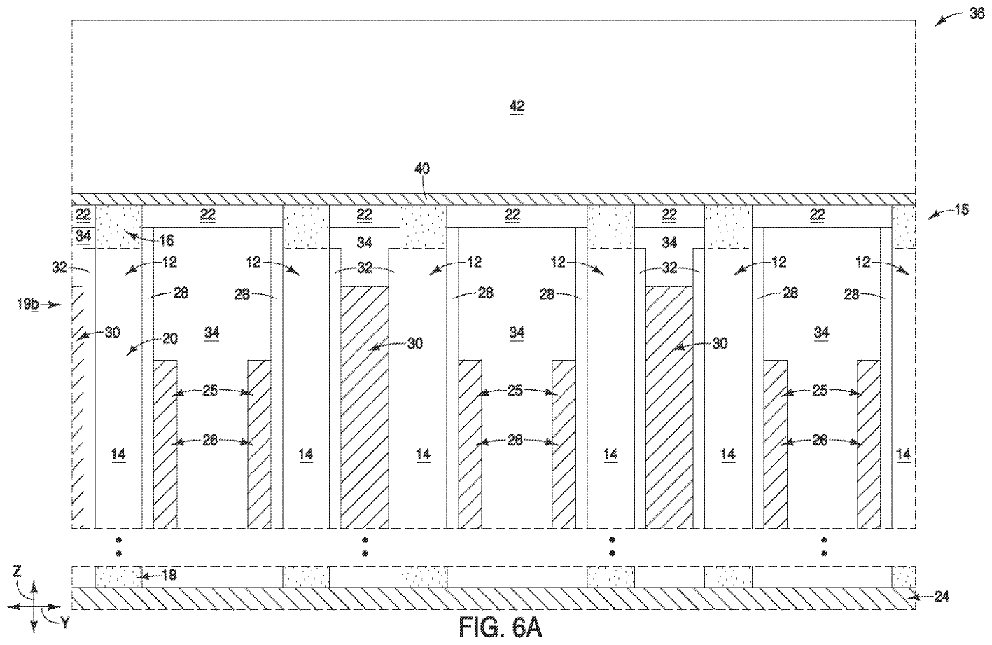

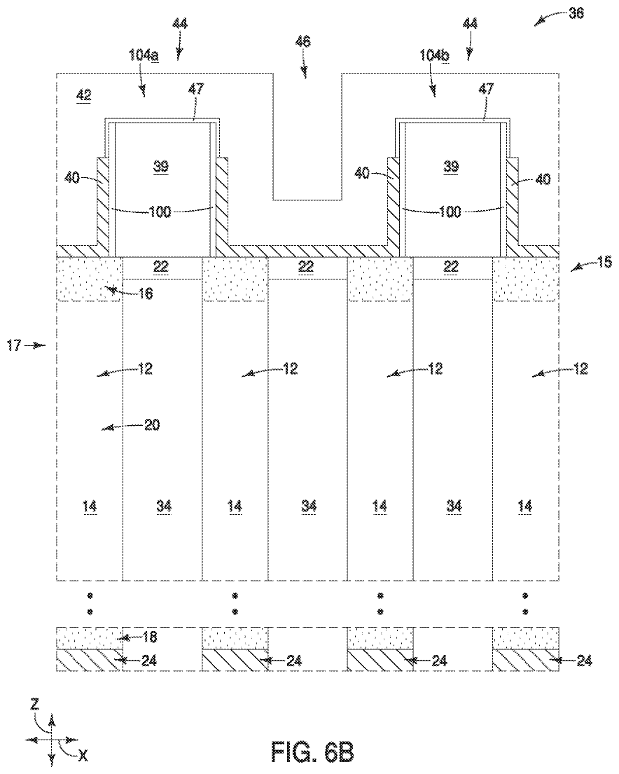

Referring to FIGS. 6-6B, a patterning material 42 is formed over the bottom-electrode-material 40. The patterning material 42 has an undulating topography which includes peaks 44 over the structures 38, and valleys 46 between the peaks. The material 42 may be formed to any suitable thickness (e.g., a thickness within a range of from about 10 nm to about 30 nm); and may comprise any suitable composition(s). In some embodiments, the material 42 may comprise, consist essentially of, or consist of one or more of silicon dioxide, silicon nitride and silicon oxynitride.

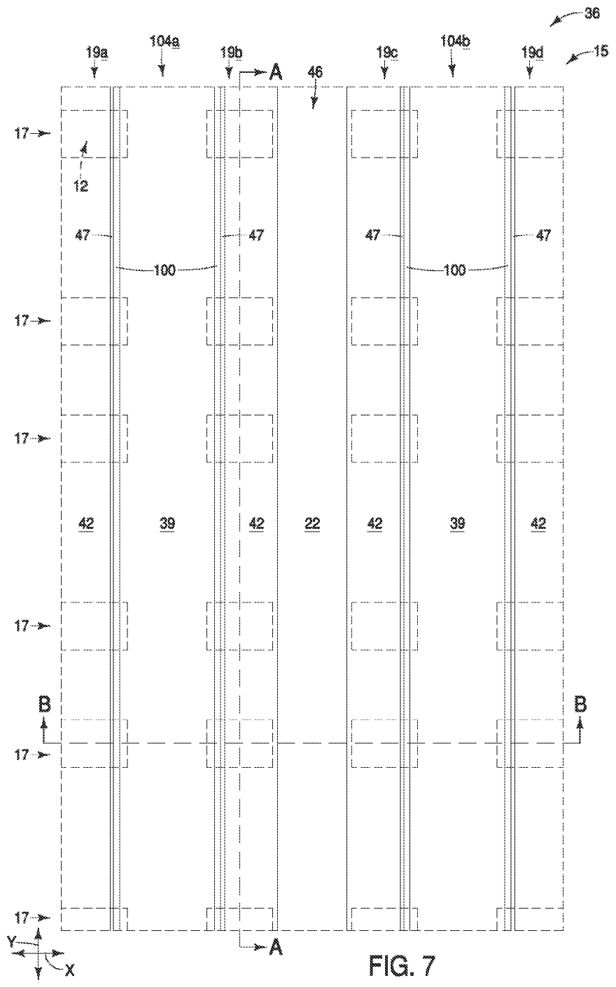

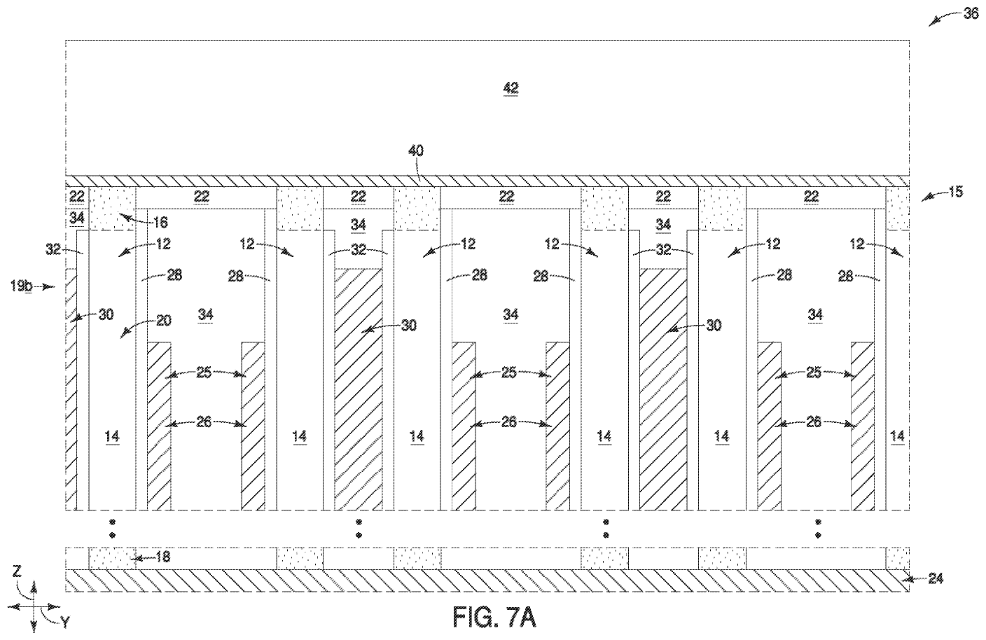

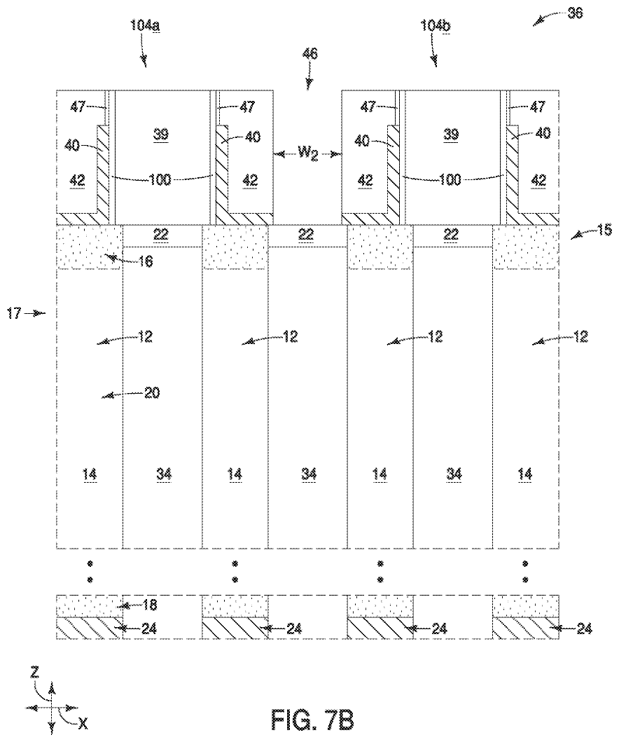

Referring to FIGS. 7-7B, the assembly 36 is subjected to one or more etches, and possibly also planarization, to remove the materials 47 and 42 from over the linear structures 104; and to extend the valleys 46 through the materials 40 and 42, and to the insulative material 22. The valleys 46 thus become openings 46 which extend through the materials 42. and 40 to the material 22. In the illustrated embodiment, the openings 46 stop at an upper surface of the material 22. and accordingly the etching may expose portions of the transistor array. In other embodiments, the openings 46 may penetrate into the material 22 (or may even penetrate through the material 22 and stop at the underlying material 34).

The illustrated embodiment shows the upper surfaces of materials 39, 100, 47 and 42 being substantially coplanar. In other embodiments at least one of such upper surfaces may be at a different elevational level relative to one or more of the others of such upper surfaces. The illustrated opening 46 may, for example, have a width W₂ along the cross-section of FIG. 7A within a range of from about 10 nm to about 30 nm.

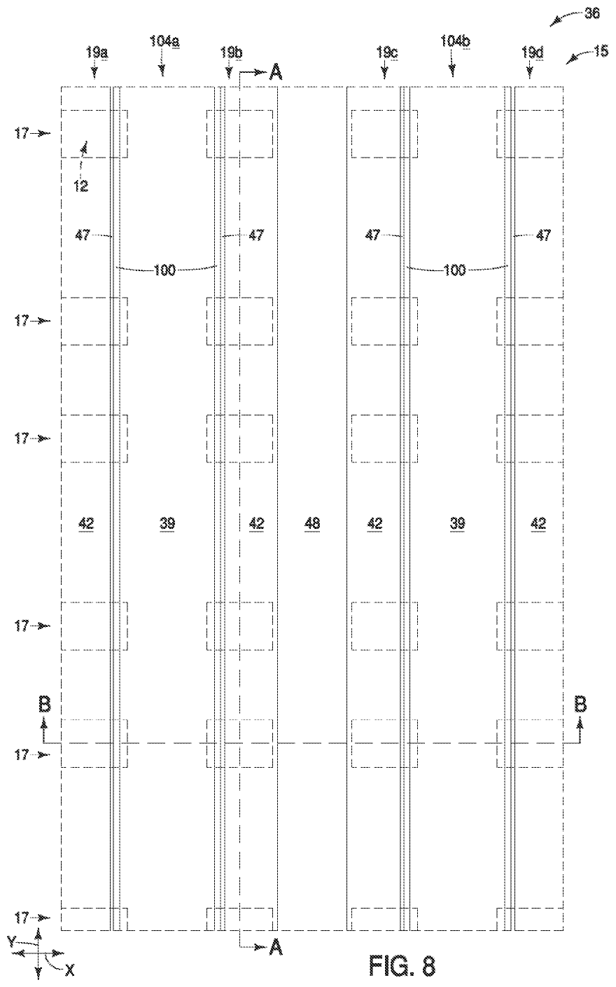

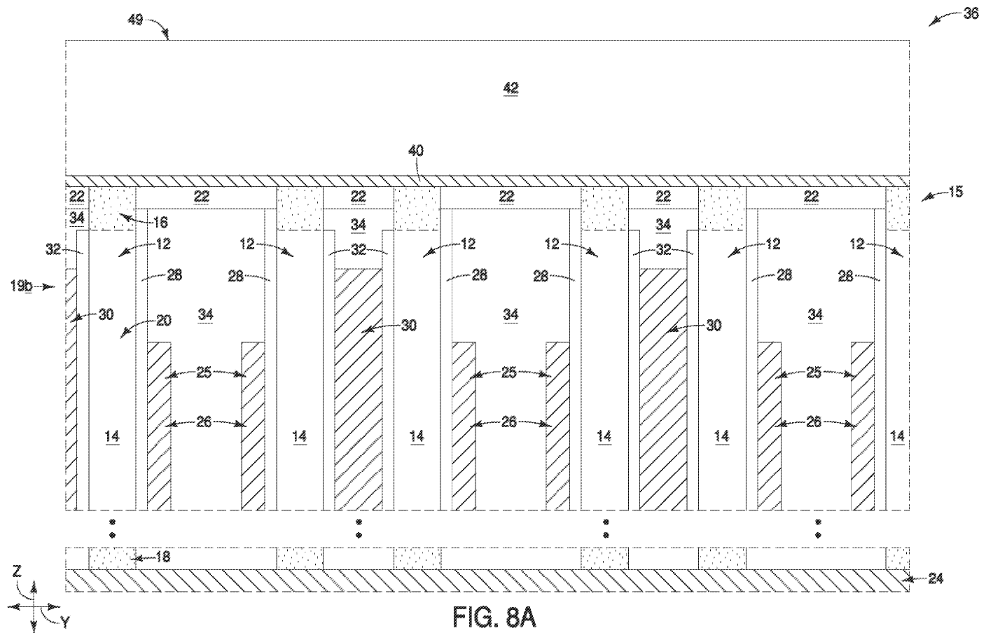

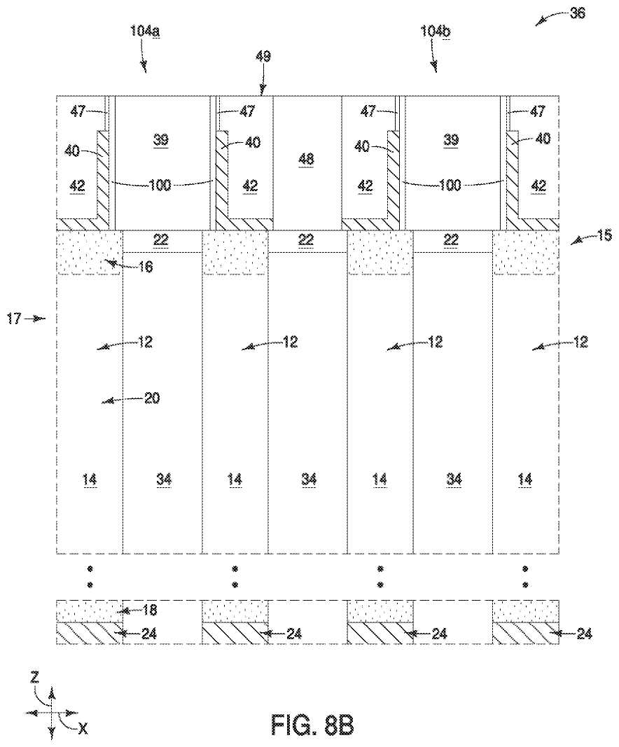

Referring to FIGS. 8-8B, fill material 48 is formed within the opening 46. Subsequently, CMP and/or other suitable planarization is utilized to form a planar surface 49 extending across the materials 39, 100, 42, 47 and 48.

The fill material 48 may comprise any suitable composition(s): and in some embodiments may comprise, consist essentially of, or consist of one or more of silicon dioxide, silicon nitride and silicon oxynitride. Accordingly, the fill material 48 may or may not be a same composition as the patterning material 42.

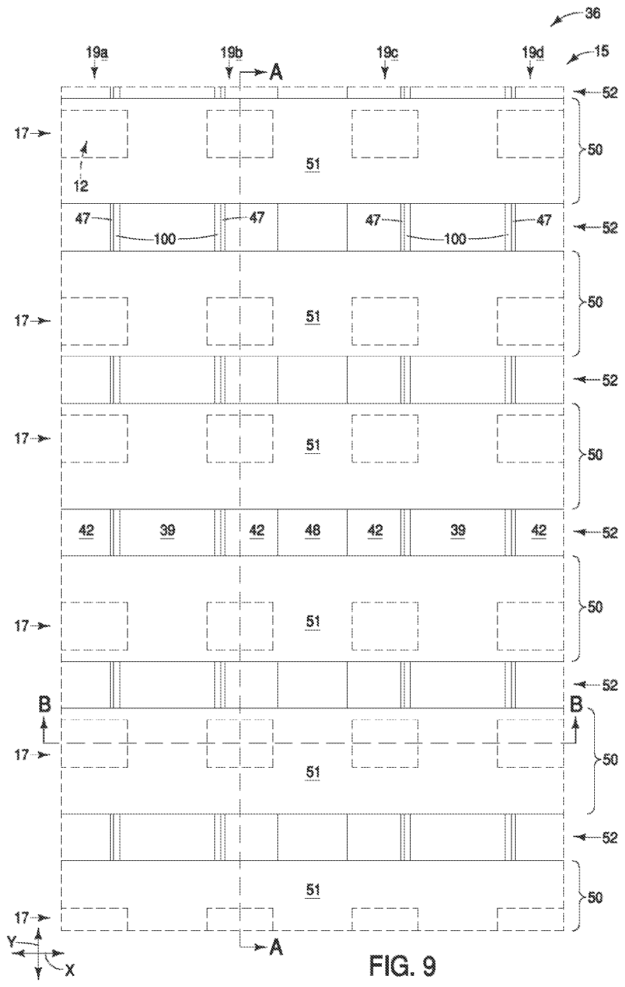

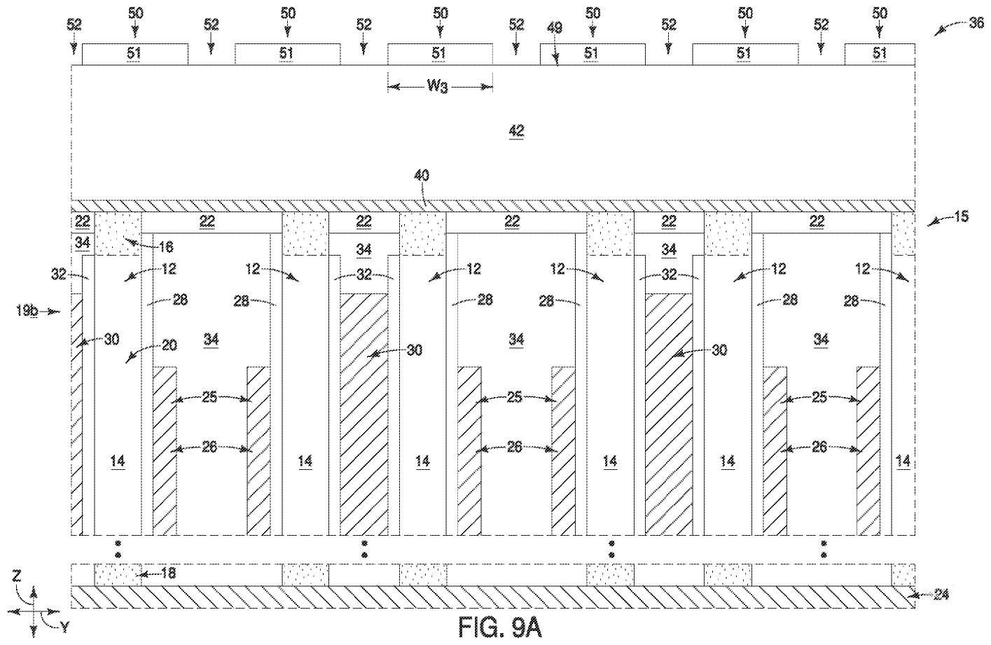

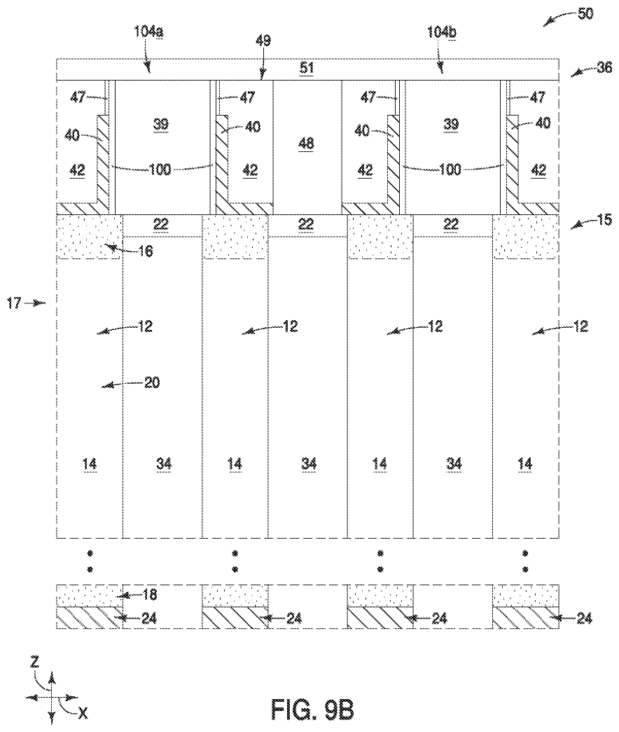

Referring to FIGS. 9-9B, mask structures (beams, rails) 50 are formed on the planar surface 49, and extend along the row direction (the illustrated x-axis direction). The mask structures 50 may comprise any suitable composition(s) 51; and in some embodiments may comprise, consist essentially of, or consist of carbon-containing material (e.g., amorphous carbon, resist, etc.).

The mask structures 50 are spaced from one another by intervening gaps 52. The mask structures 50 may have any suitable dimensions; and may, for example, have widths W₃ along the cross-section of FIG. 9A within a range of from about 10 nm to about 30 nm.

The embodiment of FIGS. 9 and 9A shows the spacings 52 to all be of about the same width along the y-axis direction. In other embodiments (not shown), some of the spacings 52 may vary in width relative to others.

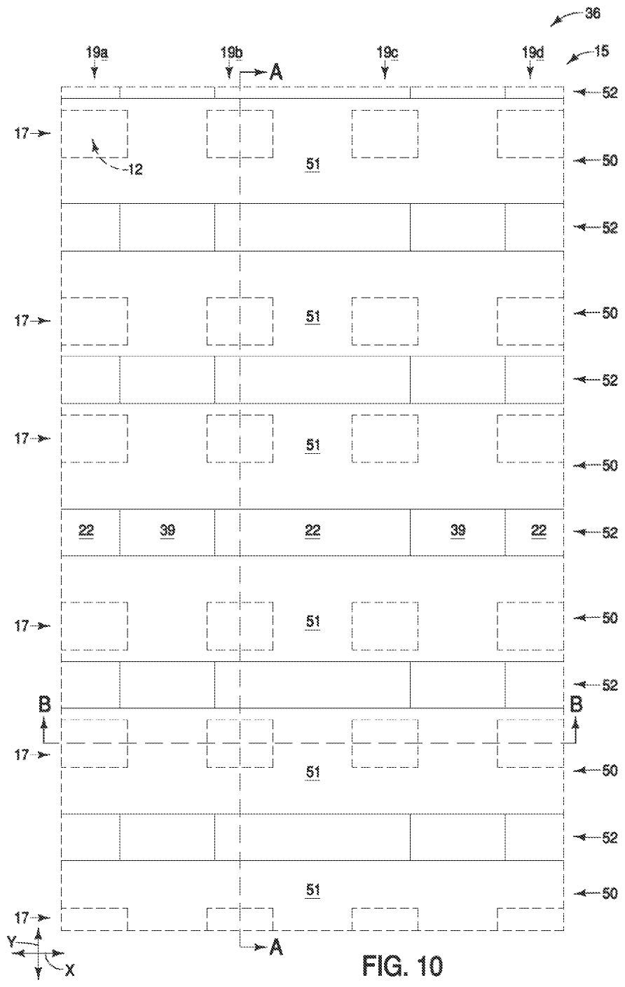

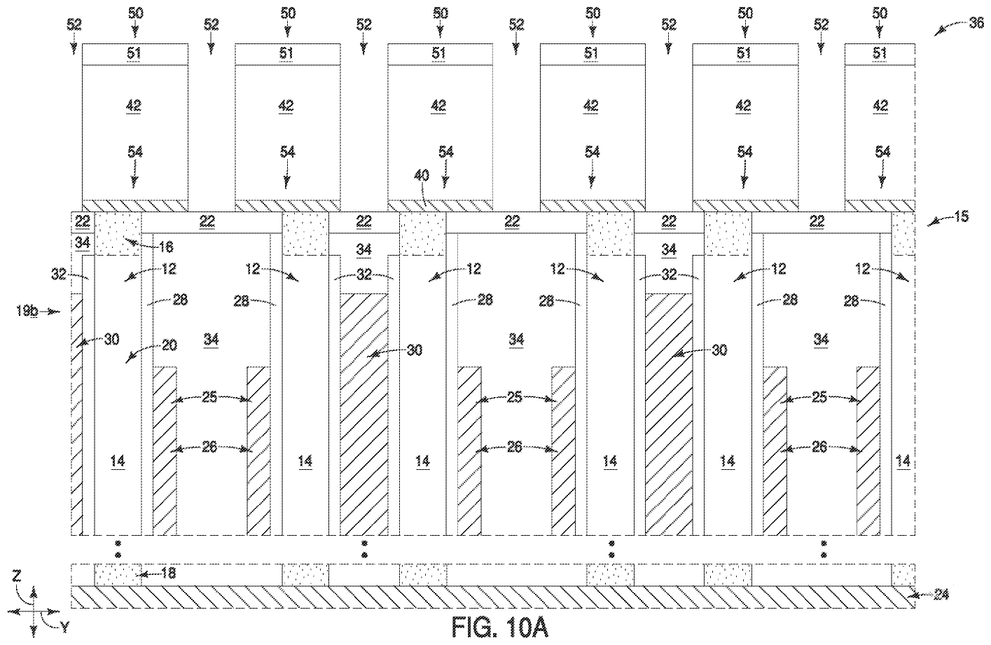

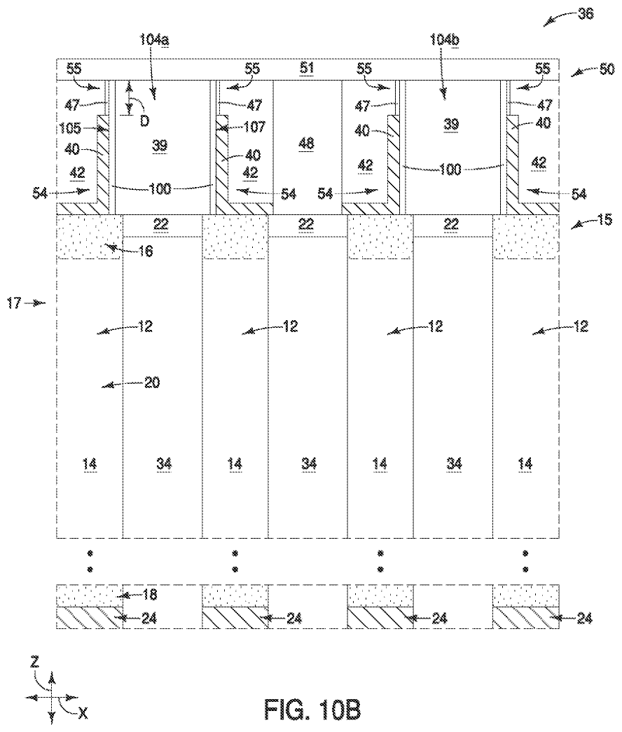

Referring to FIGS. 10-10B, the gaps 52 are extended through the materials 40, 42, 47, 48 and, in some cases, 100, and to an upper surface of the insulative material 22. In other embodiments (not shown), the gaps 52 may punch into the material 22, or even through the material 22 and into the underlying insulative material 34. Additionally or alternatively, the gaps 52 may not extend through the protective material 100 (e.g., the gaps 52 may not expose sidewalls 41 and 43 of the linear structures 104).

The gaps 52 may be extended through the materials 40, 42, 47, 48 and 100 with any suitable processing, including, for example, dry etching to anisotropically etch through the materials 40, 42, 47, 48 and, in some cases, 100. Alternatively, dry etching may be utilized to anisotropically etch through the materials 42, 47, 48 and, in some cases, 100, and then a wet etch may be utilized to extend the openings 52 through the thin layer corresponding to the bottom-electrode-material 40.

The patterning of the bottom-electrode-material 40 at the process stage of FIGS. 7-7B (which forms the bottom-electrode-material 40 into strips extending along the y-axis), and the subsequent processing shown in FIGS. 10-10B (which subdivides the strips utilizing the trenches 52 that extend along the x-axis direction) may be considered to pattern the bottom-electrode-material 40 into bottom-electrode-structures (bottom electrodes) 54. Each of the bottom-electrode-structures is over one of the source/drain regions 16 (e.g., over a contact of the transistor array), and may be considered to be associated with a corresponding one of the vertically-extending pillars 12 (e.g., corresponding to a transistor).

The processing of FIGS. 10-10B may also be considered to pattern strips of the leaker-device-material 47 (such strips are shown in the top-down view of FIG. 7) into leaker-device-structures 55 (shown in FIG. 10B). The leaker-device-structures 55 are along the sidewalls 105 and 107 of the structures 104, and are over (and directly against) the bottom-electrode-structures 54. The leaker-device-structures 55 may have any suitable vertical dimensions (vertical lengths) D, and in some embodiments such vertical dimensions may be less than or equal to about 10 nm.

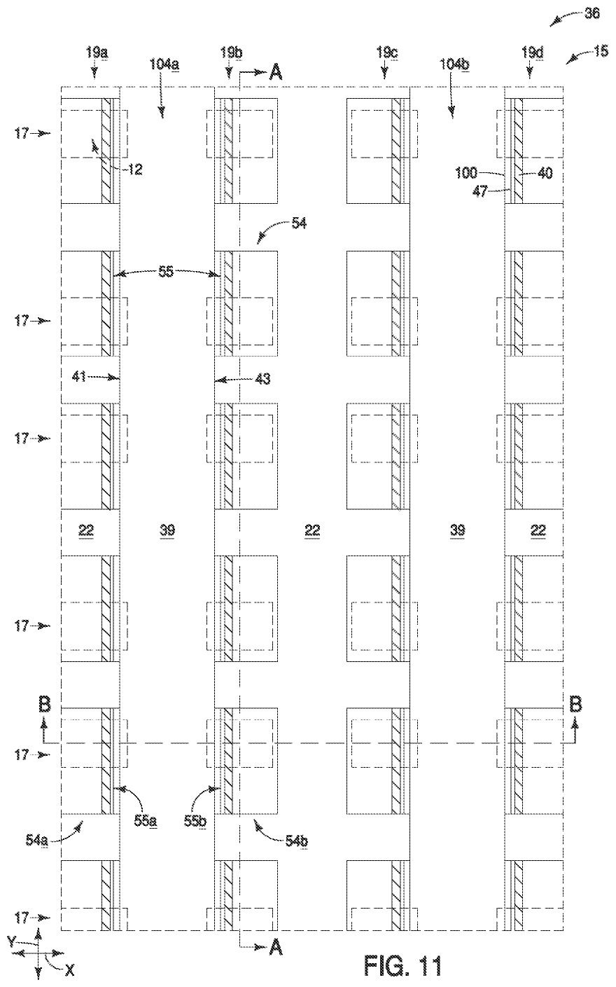

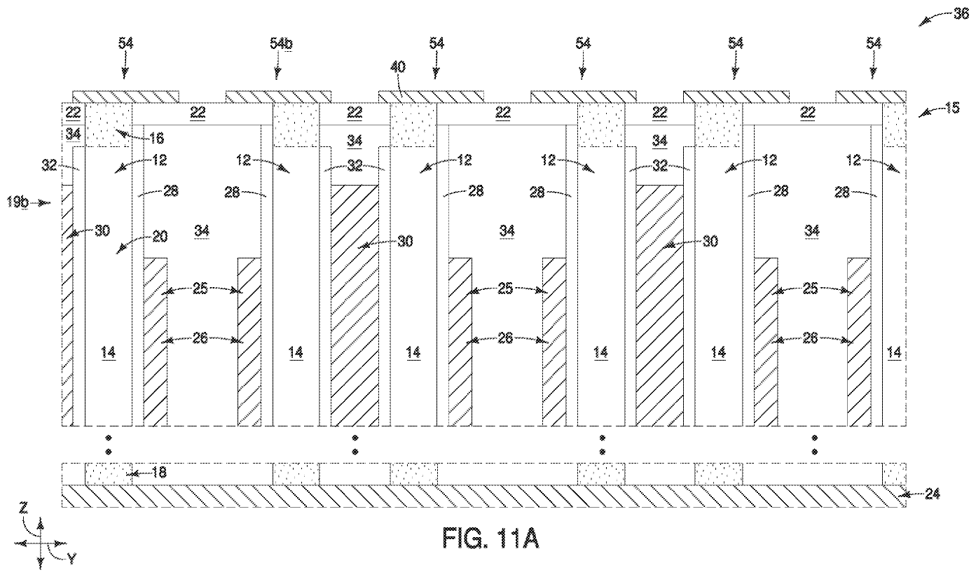

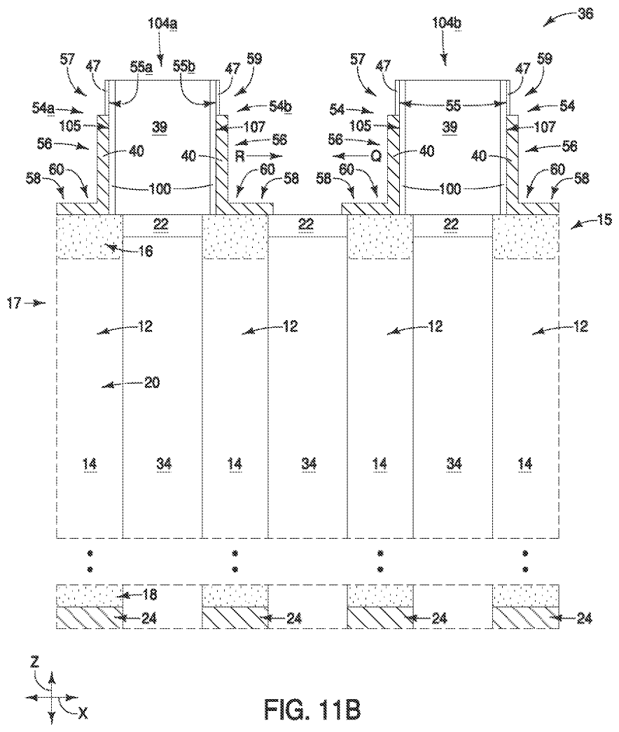

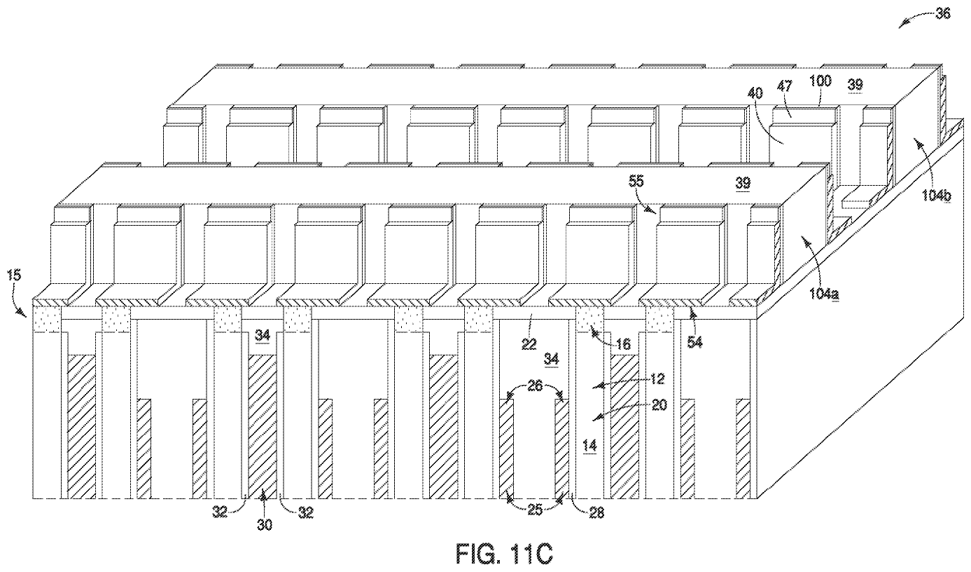

Referring to FIGS. 11-11C, the materials 51, 42 and 48 are removed with one or more suitable etches. The bottom electrodes 54 and the leaker-device-structures 55 remain.

Each of the bottom-electrode-structures 54 has a vertical segment 56 along one of sidewalls (105, 107) of a structure 104 (e.g., along a sidewall of a liner structure), and has a horizontal segment 58 along a source/drain region 16 (e.g., along a contact of the transistor array). The horizontal segments 58 join to the vertical segments 56 at corners 60. The corners 60 may be about 90° (i.e., may be approximately right angles), with the term “about 90°” meaning 90° to within reasonable tolerances of fabrication and measurement. In some embodiments, the term about 90° may mean 90°±10°.

In some embodiments, the horizontal segments 58 may be referred to as first segments and the vertical segments 56 may be referred to as second segments. The first and second segments 58 and 56 may or may not be substantially orthogonal to one another, depending on whether the sidewalls (105, 107) are vertical (as shown) or tapered.

In the illustrated embodiment, the vertical segments 56 are longer than the horizontal segments 58. In other embodiments, the segments 56 and 58 may be about the same length as one another, or the horizontal segments 58 may be longer than the vertical segments 56.

The bottom-electrode-structures 54 may be considered to be configured as angle plates, and in the shown embodiment are in one-to-one correspondence with the upper source/drain regions 16. Each of the bottom electrodes 54 may be considered to be electrically coupled with an associated source/drain region 16 of an associated pillar 12.

The bottom-electrode-structures 54 adjacent the first sidewalls 105 of the structures 104 may be considered to correspond to a first set 57 of the bottom-electrode-structures 54, and the bottom-electrode-structures 54 adjacent the second sidewalls 107 of the linear structures 104 may be considered to correspond to a second set 59 of the bottom-electrode-structures 54. The horizontal segments 58 of the bottom electrodes 54 within the first set 57 project in a first direction Q (with direction Q being shown in FIG. 11B), and the horizontal segments 58 of the bottom electrodes 54 within the second se 59 project in a second direction R (with direction R being shown in FIG. 11B). The direction R is opposite to the direction Q. In some embodiments, the bottom electrodes of the first set 57 may be considered to be substantially mirror images of the bottom electrodes of the second set 59, where the term “substantial mirror image” means a mirror image to within reasonable tolerances of fabrication and measurement.

Two of the bottom electrodes 54 of FIGS. 11-11B are labeled as 54a and 54b, and such may be referred to as a first and second bottom electrodes, respectively. The leaker-device-structures extending upwardly from the bottom electrodes 54a and 54b are labeled as 55a and 55b, and may be referred to as first and second leaker-device-structures, respectively.

Although the example depicted in FIGS. 11-11C may illustrate an example in which the protective material 100 is interrupted between adjacent electrode segments 54, other examples are contemplated. For example, the protective material 100 may not be etched during formation of the electrode segments 54, such that the protective material 100 may cover the sidewalls 41 and 43 of the linear structures 104.

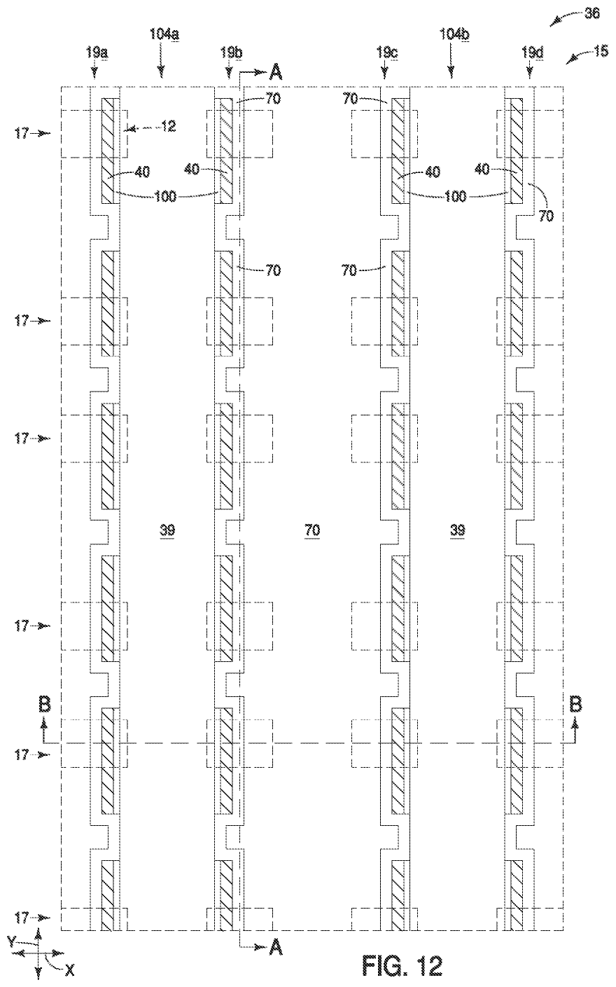

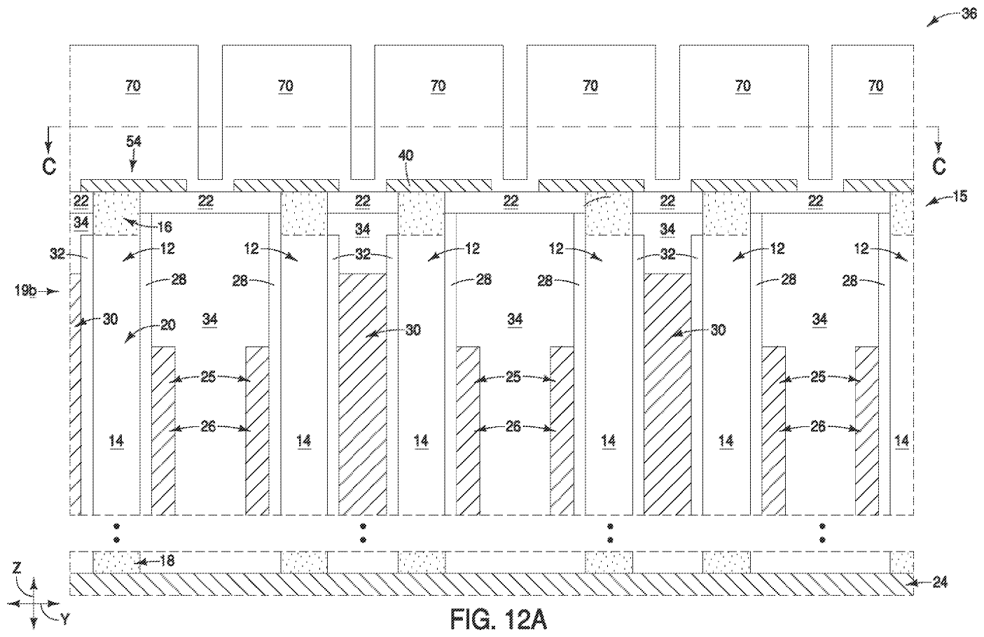

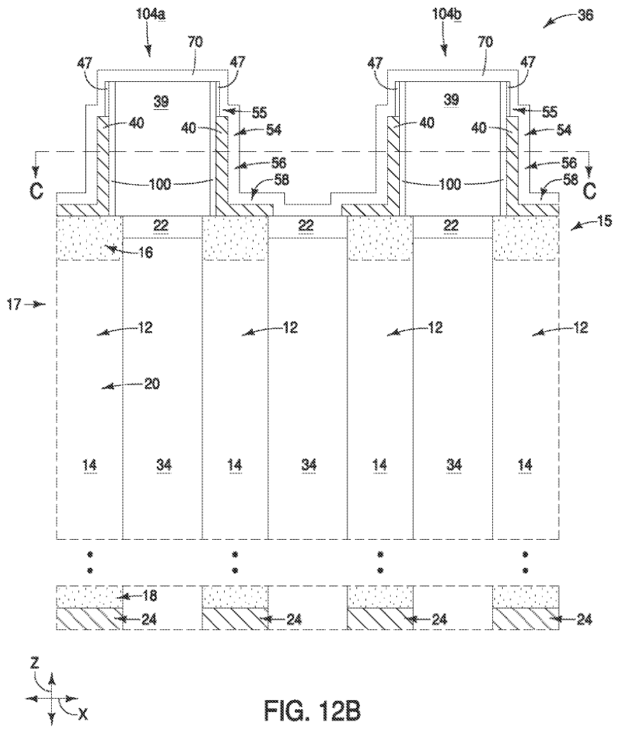

Referring to FIGS. 12-12B, capacitor-insulative-material (e.g., ferroelectric-insulative-material) 70 is formed to be over and directly against the bottom-electrode-structures 54. It is noted that FIG. 12 is a top-down view along the lines C-C of FIGS. 12A and 12B.

In the shown embodiment, the capacitor-insulative-material 70 extends across the material 22 between the bottom electrodes 54, as well as extending over the bottom electrodes. The material 70 also extends over the linear structures 104. The capacitor-insulative-material 70 is laterally adjacent to the leaker-device-structures 55, is laterally adjacent to the vertical segments 56 of the bottom electrodes (e.g., sidewalls of the bottom electrodes), and is over the horizontal segments 58 of the bottom electrodes. In some cases, the capacitor-insulative-material 70 may also be over the material 22 (e.g., may be over a portion of the transistor array).

The capacitor-insulative-material 70 may comprise any suitable composition or combination of compositions, including, for example, silicon dioxide, silicon nitride, etc. In some embodiments, the capacitor-insulative-material 70 may be ferroelectric-insulative-material; and in some example embodiments the ferroelectric-insulative-material may include one or more of transition metal oxide, zirconium, zirconium oxide, niobium, niobium oxide, hafnium, hafnium oxide, lead zirconium titanate, and barium strontium titanate. Also, in some example embodiments the ferroelectric-insulative-material may have dopant therein which comprises one or more of silicon, aluminum, lanthanum, yttrium, erbium, calcium, magnesium, strontium, and a rare-earth element.

The capacitor-insulative-material 70 may be formed to any suitable thickness; and in some embodiments may be formed to a thickness within a range of from about 30 Å to about 250 Å.

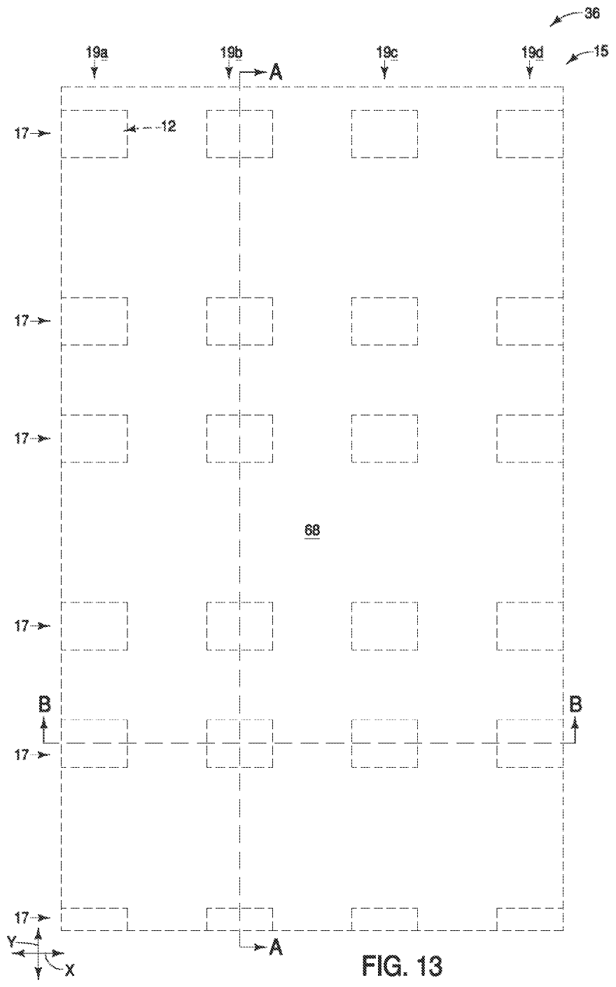

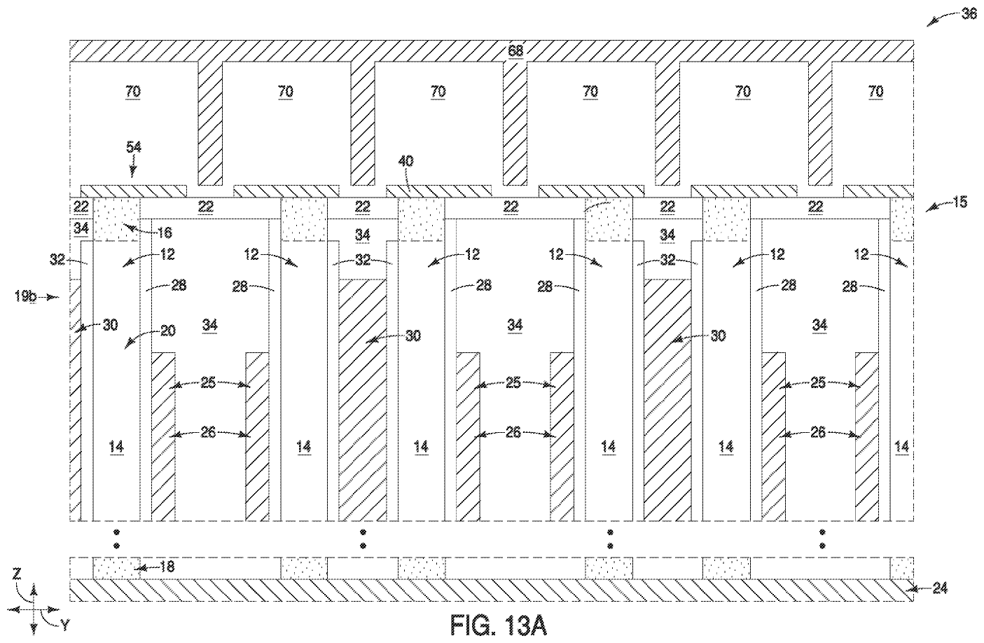

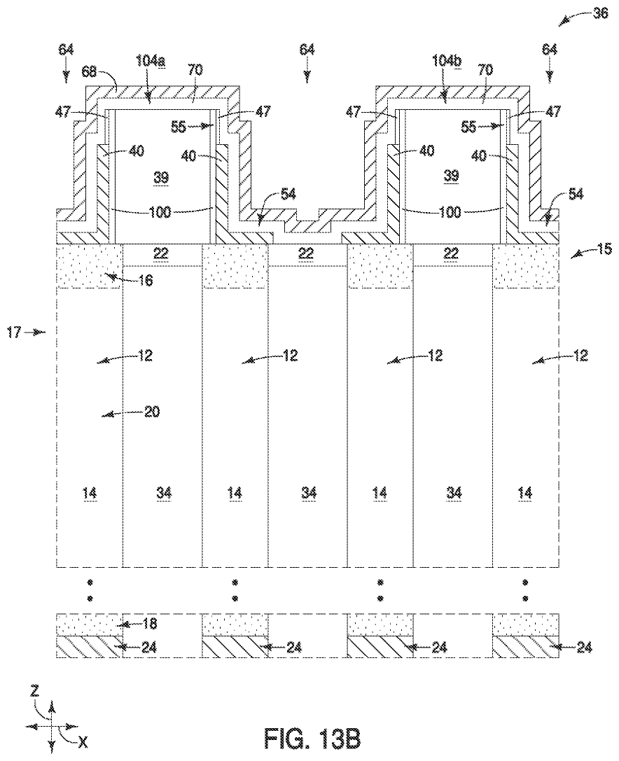

Referring to FIGS. 13-13B, top-electrode-material 68 is formed (e.g., deposited) over the insulative-material 70.

The top-electrode-material 68 may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.). In some embodiments, the top-electrode-material 68 may comprise, consist essentially of, or consist of one or more of molybdenum silicide, titanium nitride, titanium silicon nitride, ruthenium silicide, ruthenium, molybdenum, tantalum nitride, tantalum silicon nitride and tungsten. In some embodiments, the top electrode material 68 may comprise, consist essentially of, or consist of titanium nitride.

The top-electrode-material 68 may have any suitable thickness, and in some embodiments may have a thickness of at least about 10 Å, at least about 100 Å, at least about 500 Å, etc.

The electrode materials 40 and 68 may comprise a same composition as one another in some embodiments, or may comprise different compositions relative to one another. In some embodiments, the electrode materials 40 and 68 may both comprise, consist essentially of, or consist of titanium nitride.

The embodiment of FIGS. 13-13B shows gaps 64 (FIG. 13B) in regions between the structures 104a and 104b. In some embodiments, the electrode material 68 may be formed thick enough to fill such gaps.

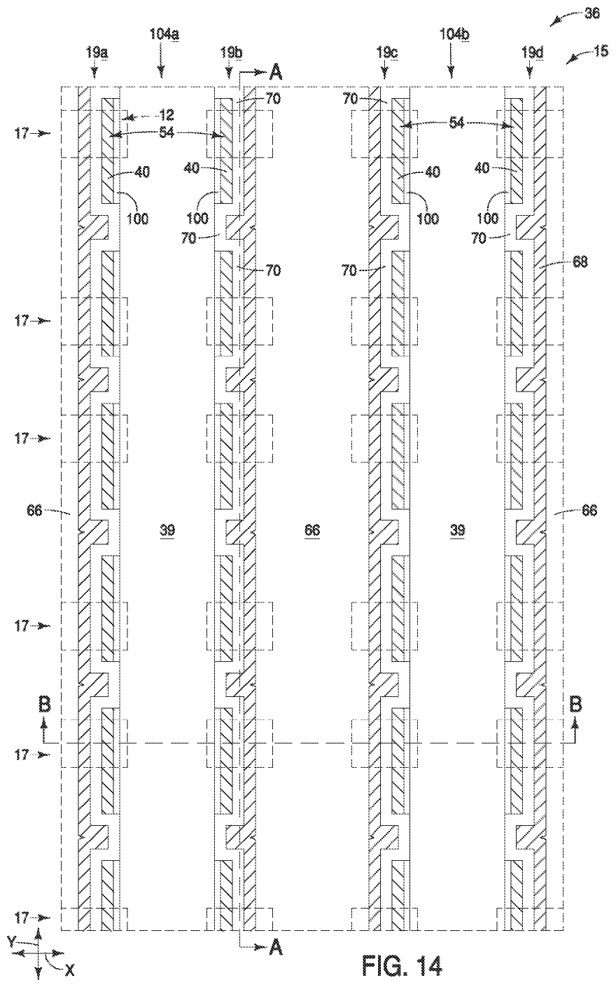

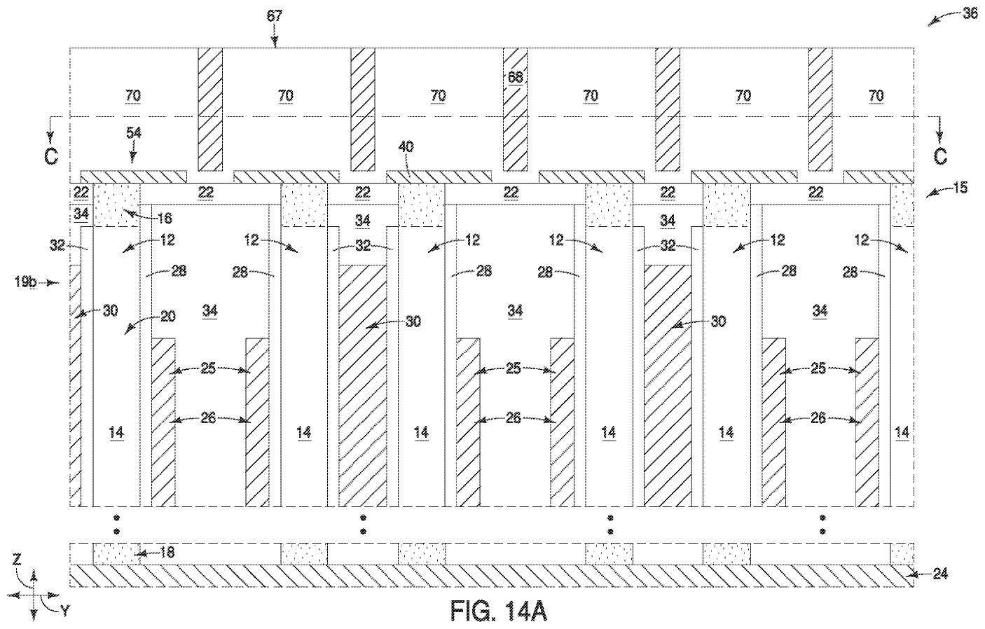

Referring to FIGS. 14-14B, protective material 66 is formed within the gaps 64, and subsequently planarization (e.g., CMP) is utilized to form a planarized surface 67. Upper edges 65 of the leaker-device-structures 55 are exposed along the surface 67.

The protective material 66 may comprise any suitable composition(s), such as, for example, silicon dioxide, silicon nitride, carbon, photoresist, etc. If the material 68 fills the gaps 64 at the process stage of FIGS. 13-13B, the protective material 66 of FIGS. 14-14B may be omitted.

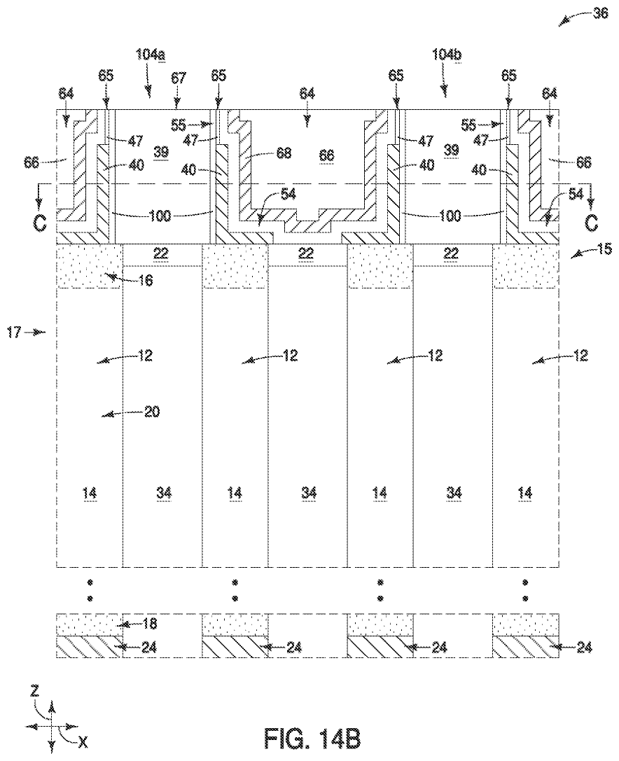

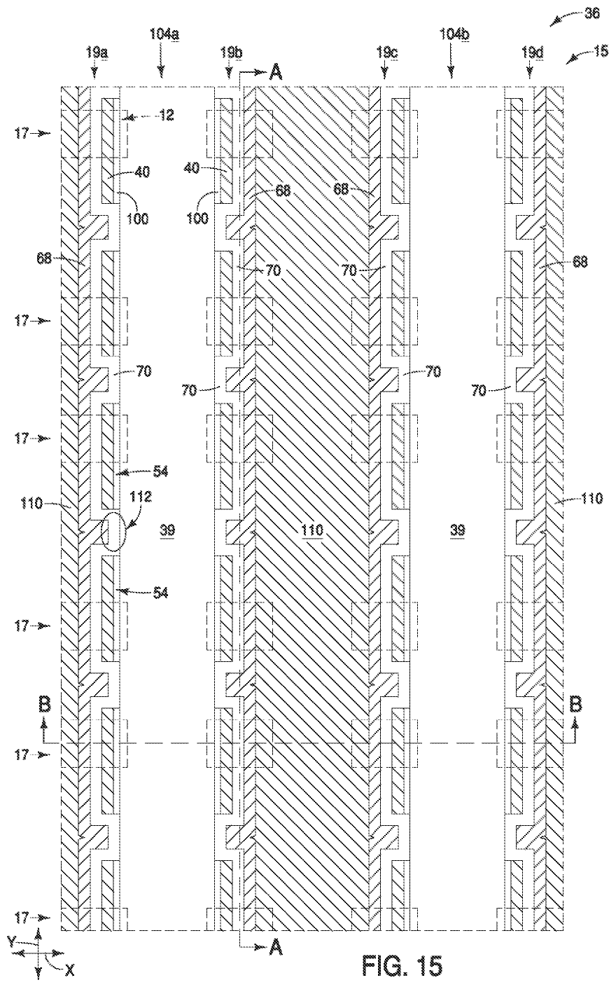

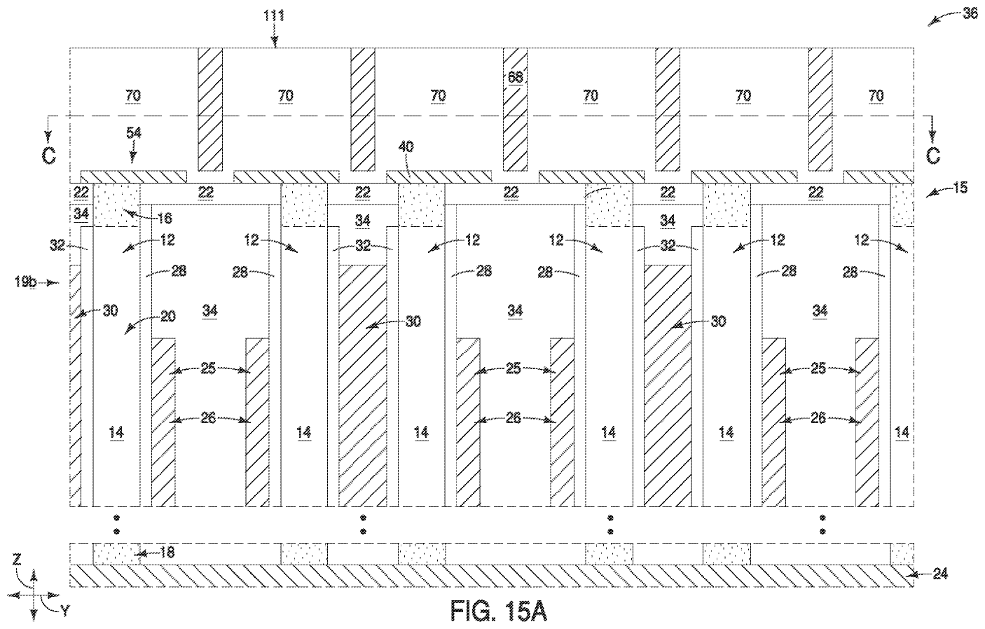

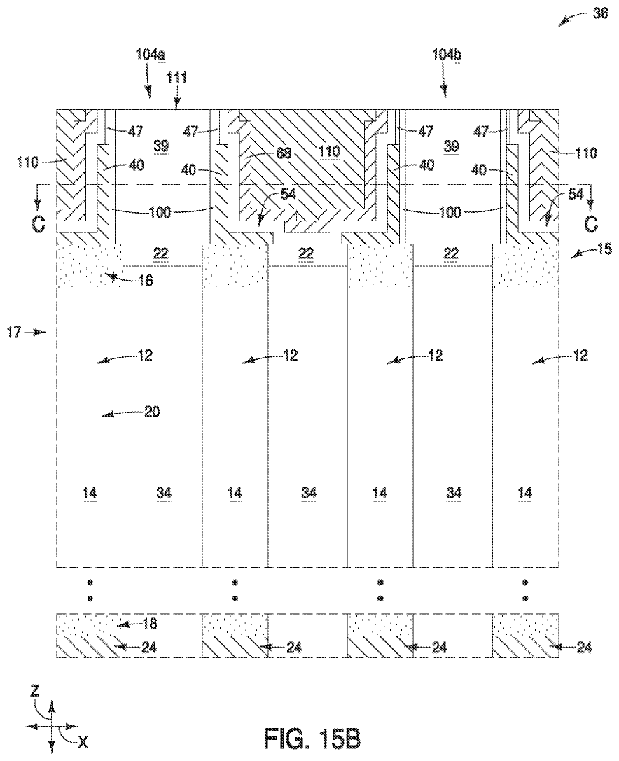

Referring to FIGS. 15-15B, the protective material 66 is removed, additional conductive material 110 is formed, and a planarized surface 111 is formed to expose the material 39 of the structures 104. If the conductive material 68 fills the gap 64 at the process stage of FIGS. 13-13B, the process stage of FIGS. 14-14B may be omitted and the process stage of FIGS. 15-15B may simply follow that of FIGS. 13-13B.

The conductive material 110 may comprise any of the compositions described above as being suitable for the conductive material 68, and may or may not comprise a same composition as the conductive material 68.

FIG. 15 shows that the insulative-material 70 extends into gaps in regions 112 between neighboring bottom electrodes 54. Only some of the regions 112 are labeled. The insulative-material 70 (particularly ferroelectric-insulative-material) within the regions 112. may undesirably enable cross-talk between adjacent bottom electrodes. Accordingly, some embodiments include methods of removing the insulative-material 70 from within the regions 112. In some embodiments, the regions 112 may be referred to as intervening regions.

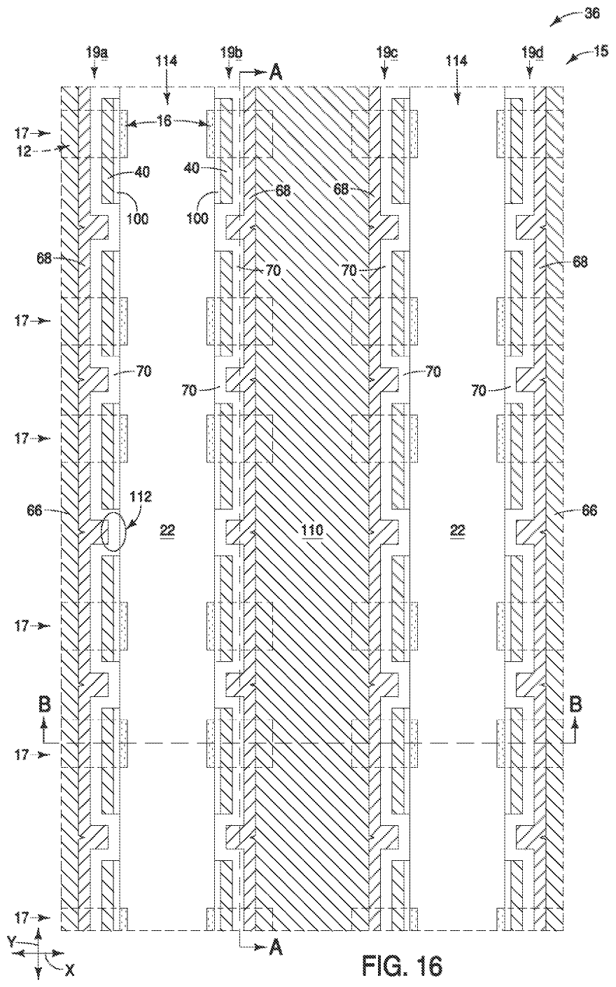

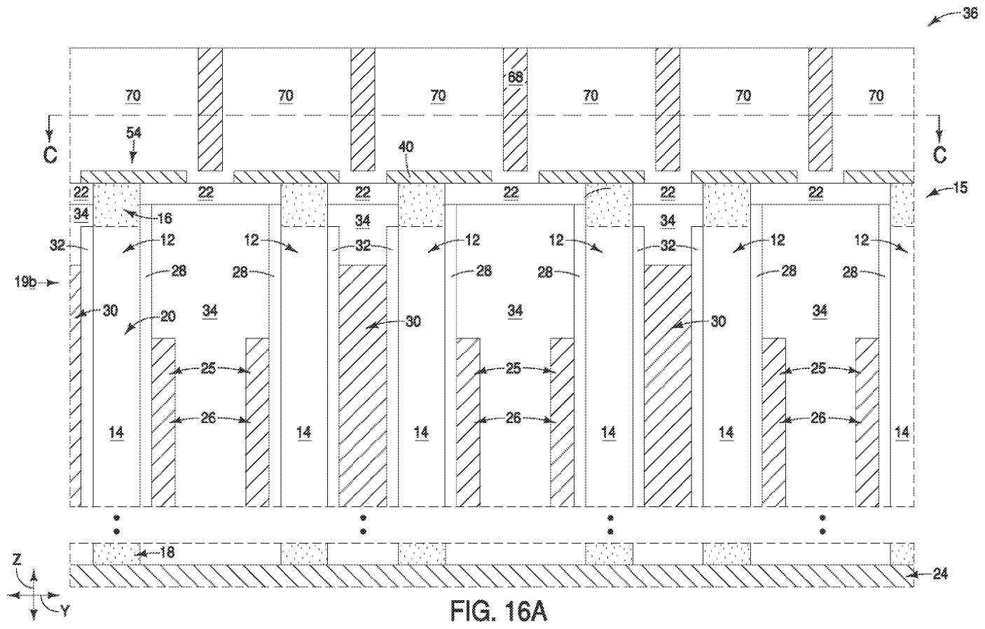

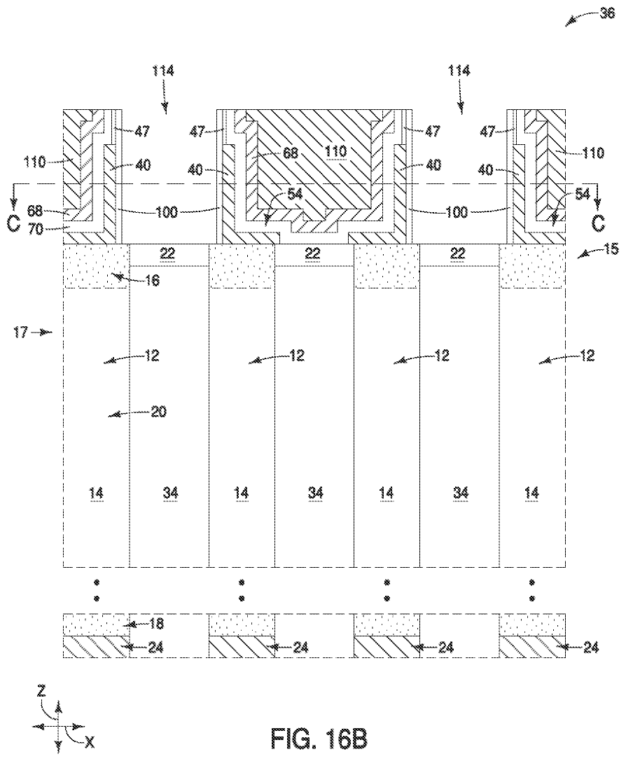

Referring to FIGS. 16-16B, the sacrificial material 39 (FIGS. 15-15B) is removed to form trenches (openings) 114. Portions (segments, regions) of the insulative-material 70 are exposed along sidewalls of the trenches 114 within the regions 112.

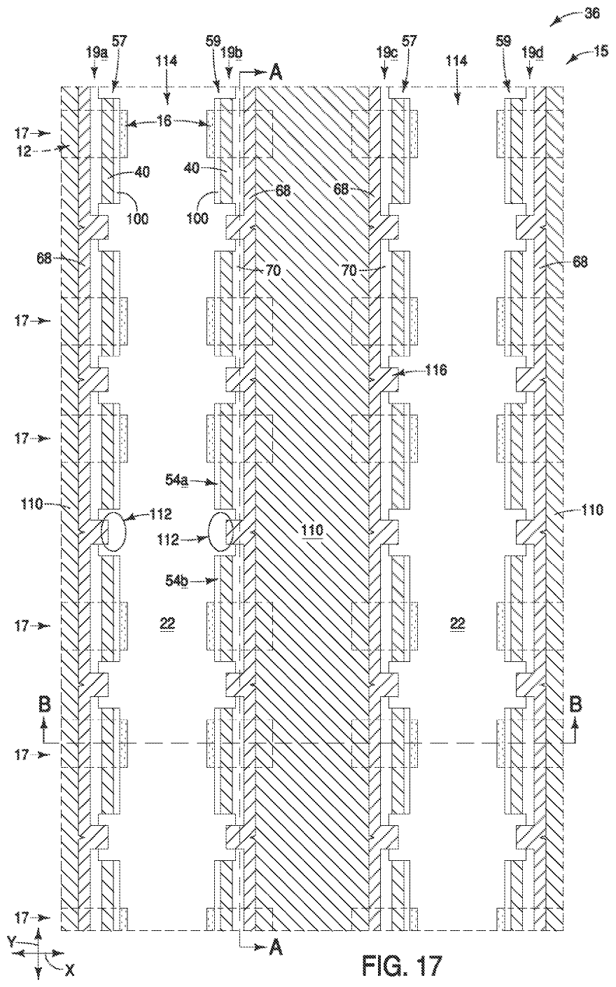

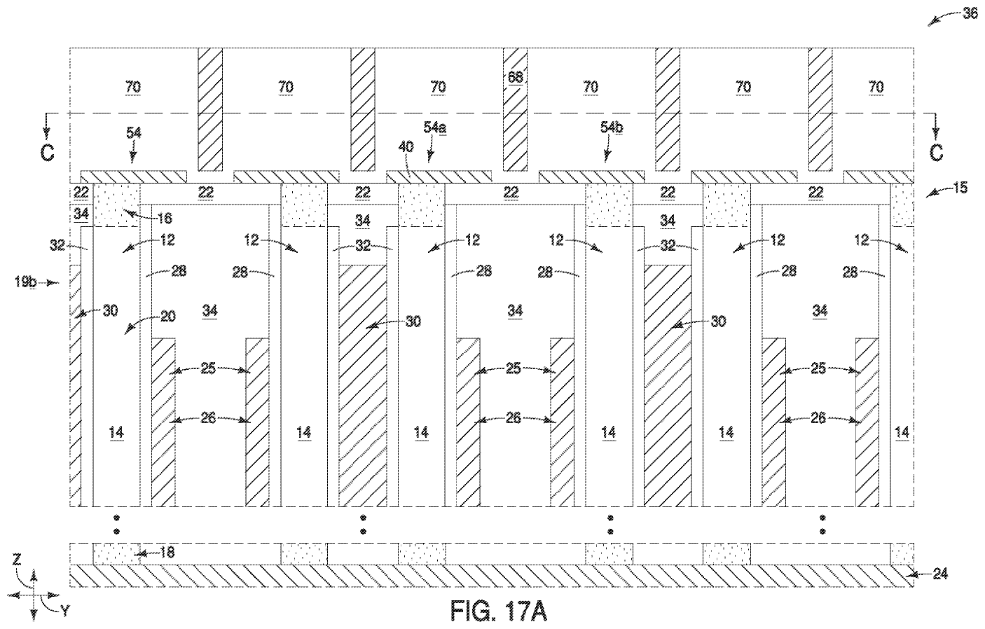

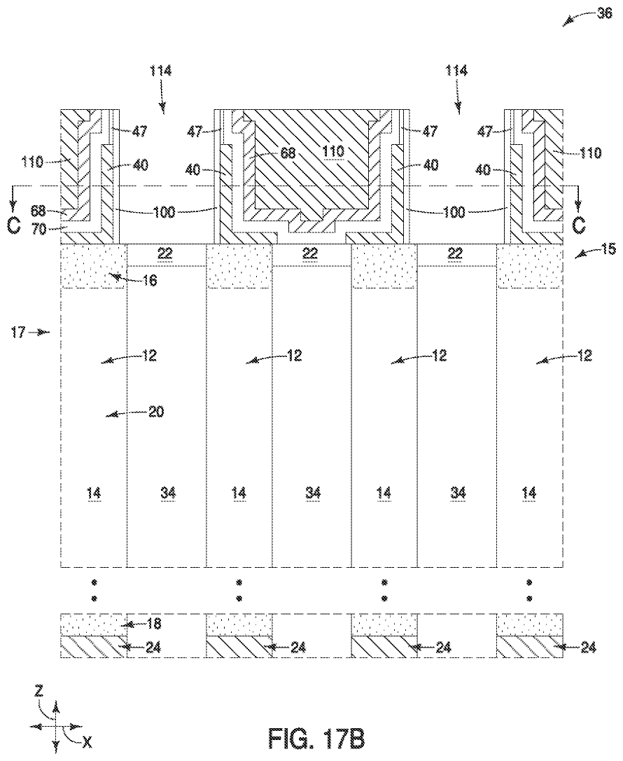

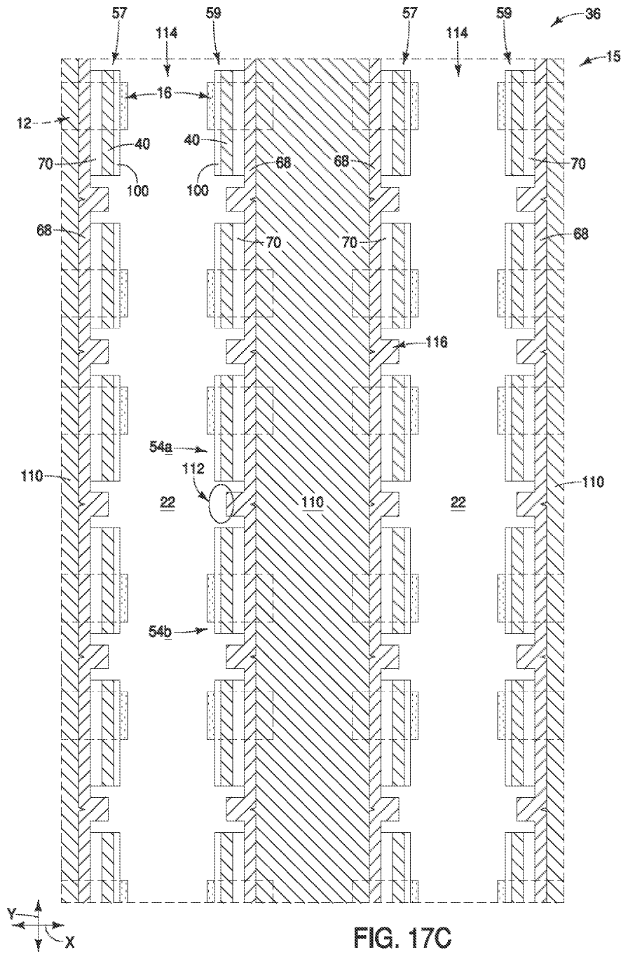

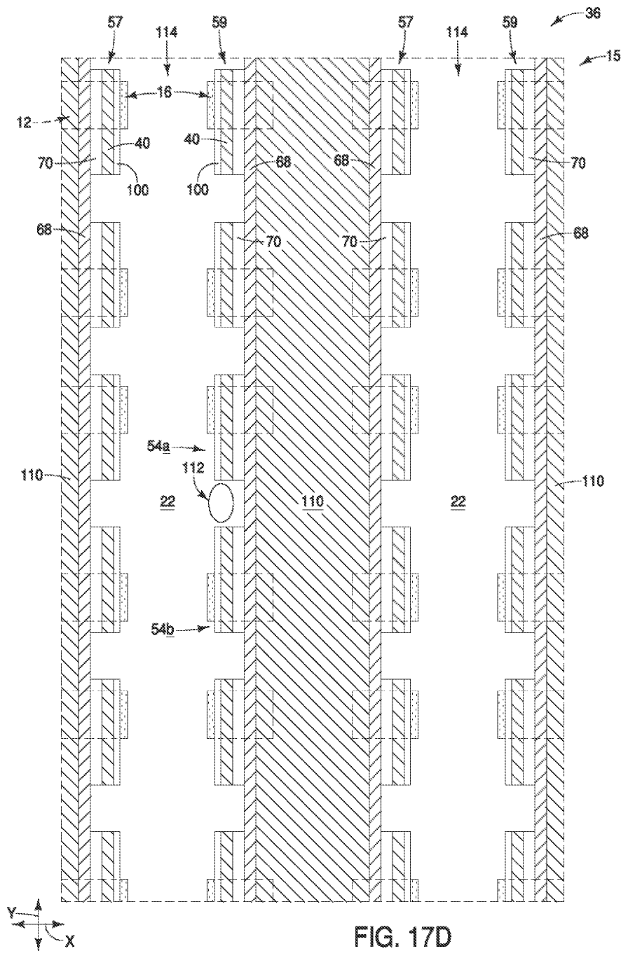

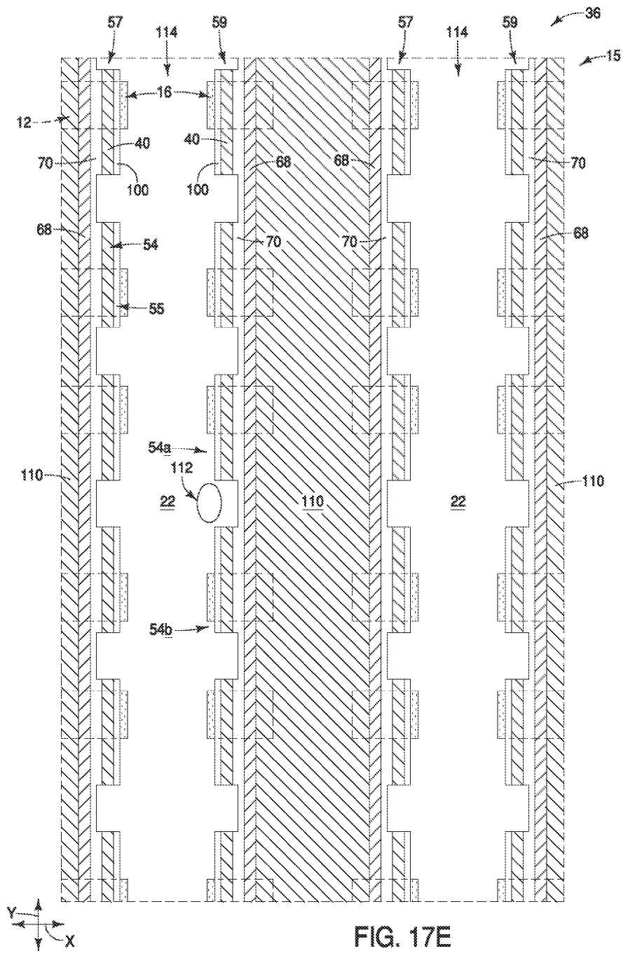

Referring to FIGS. 17-17B, the exposed regions of the insulative-material 70 (i.e., the regions of material 70 exposed within the regions 112 of FIG. 16) are recessed to alleviate (or even prevent) cross-talk between neighboring bottom electrodes 54 that may occur without the recessing of the capacitor-insulative-material. FIG. 17 shows an embodiment in which the insulative-material 70 is recessed to a depth which removes it from being directly between longitudinally adjacent bottom electrodes 54 (e.g., from between the electrodes 54 labeled 54a and 54b in FIGS. 17 and 17a), which leaves a gap shown in a region 112 of FIG. 17a. In some embodiments, the entirety of the insulative-material 70 may be removed from within the regions 112, as shown in FIG. 17C. In some embodiments, the embodiment of FIG. 17 may be considered to have some of the insulative-material 70 extending longitudinally between the longitudinally-adjacent electrodes 54a and 54b, even though the material 70 is recessed from being directly between the electrodes 54a and 54b. In contrast, the embodiment of FIG. 17C has substantially none (or even absolutely none) of the material 70 extending longitudinally between the electrodes 54a and 54b.

The embodiments of FIGS. 17 and 17C show portions (regions) 116 of the conductive material 68 projecting into the regions 112. In some embodiments, processing may be conducted to either remove the portions 116, or to eliminate formation of the portions 116. FIGS. 17D and 17E show embodiments in which the portions 116 of the conductive material 68 are omitted. FIG. 17D shows the material 70 substantially entirely omitted from the regions 112, and FIG. 17E shows the material 70 recessed within the regions 112 so that it is no longer directly between neighboring bottom electrodes (e.g., so that it is not directly between the longitudinally adjacent electrodes 54a and 54b).

In some embodiments, the configurations of FIGS. 17, 17C, 17D and 17E may be considered to have the capacitor-insulative-material 70 substantially absent (or entirely absent) from being directly between the bottom electrodes of the first and second sets 57 and 59; with the term “substantially absent” meaning absent to within reasonable tolerances of fabrication and measurement.

In some cases, the process stage of FIGS. 16-17E may be omitted, such that the material 39 of the liner structures 104 may not be removed during the process stage of FIGS. 16-17E.

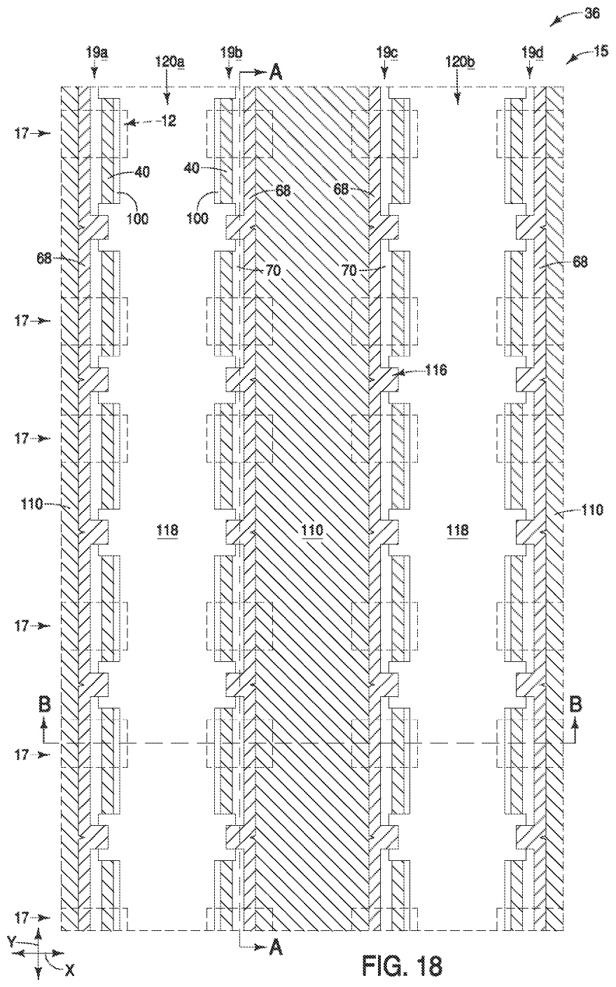

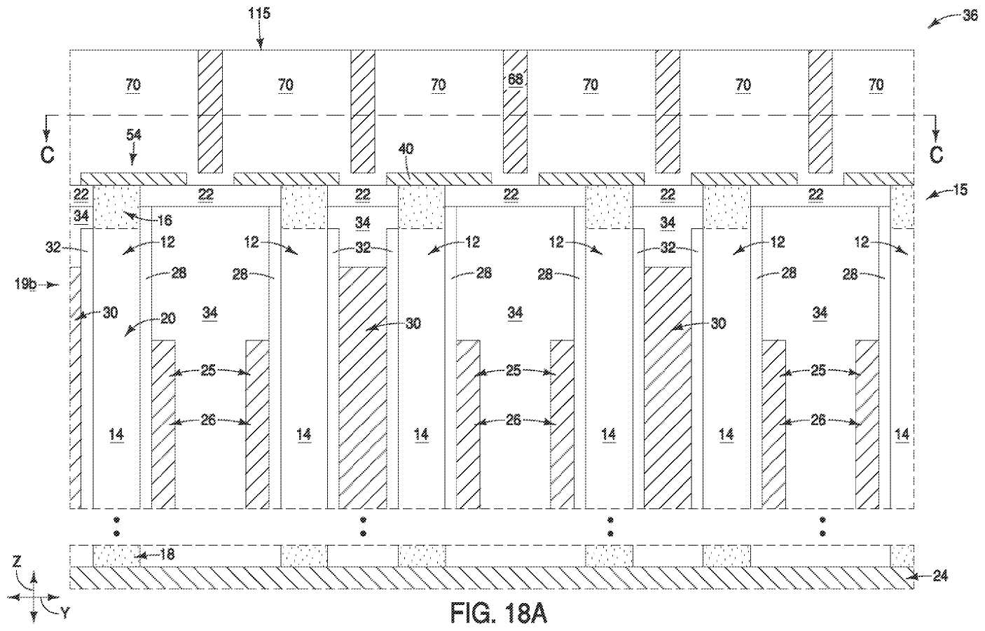

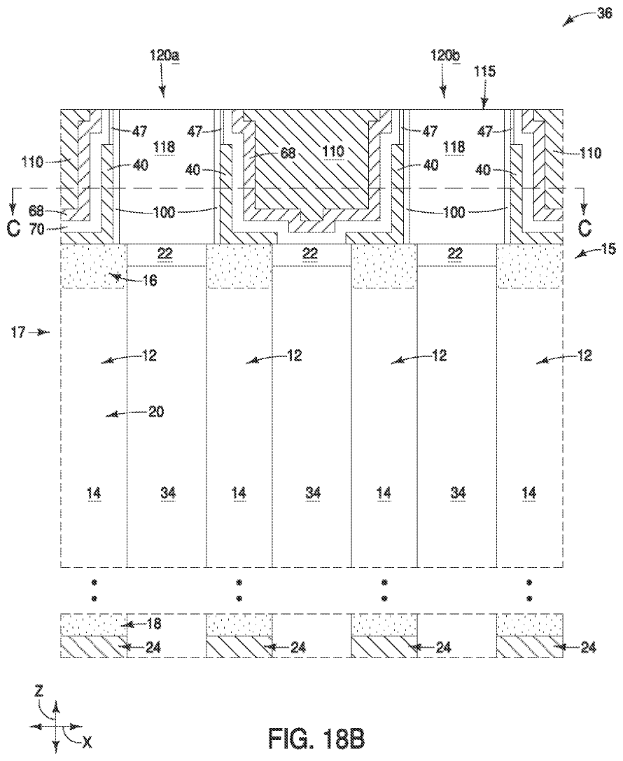

Referring to FIGS. 18-18B, sacrificial material 118 is formed within the trenches 114 (FIGS. 17-17B). The sacrificial material 118 may comprise any suitable composition(s), including, for example, one or more of silicon dioxide, silicon nitride, aluminum oxide, etc. The insulative materials 118 and 100 may be together considered to form linear structures 120 (labeled 120a and 120b). The linear structures 120 may be referred to as second linear structures to distinguish them from the linear structures 104 described above. Additionally or alternatively, if the process stage of FIGS. 16-17E are omitted, the linear structures 120 may be the same linear structures 104. In such cases, the sacrificial material 118 may be the same material as the material 39.

A planarized surface 115 is formed to extend across the materials 118, 100, 47, 70, 68 and 110.

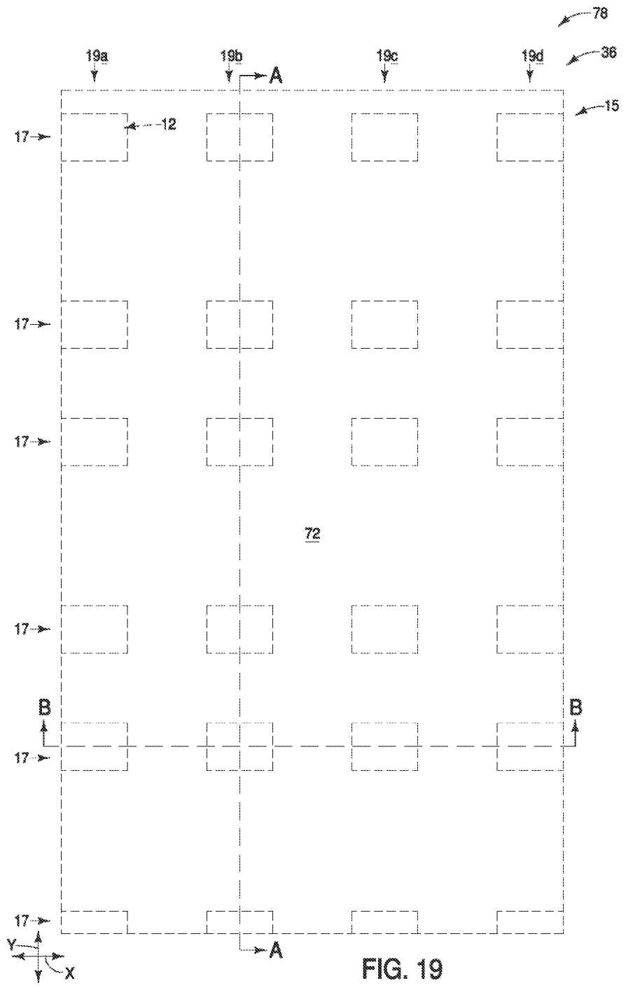

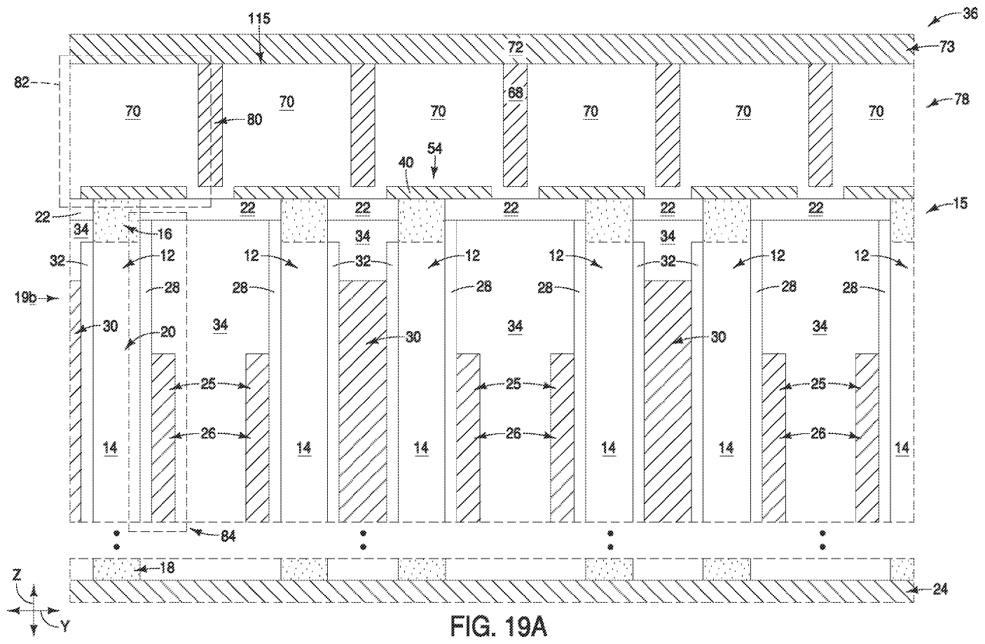

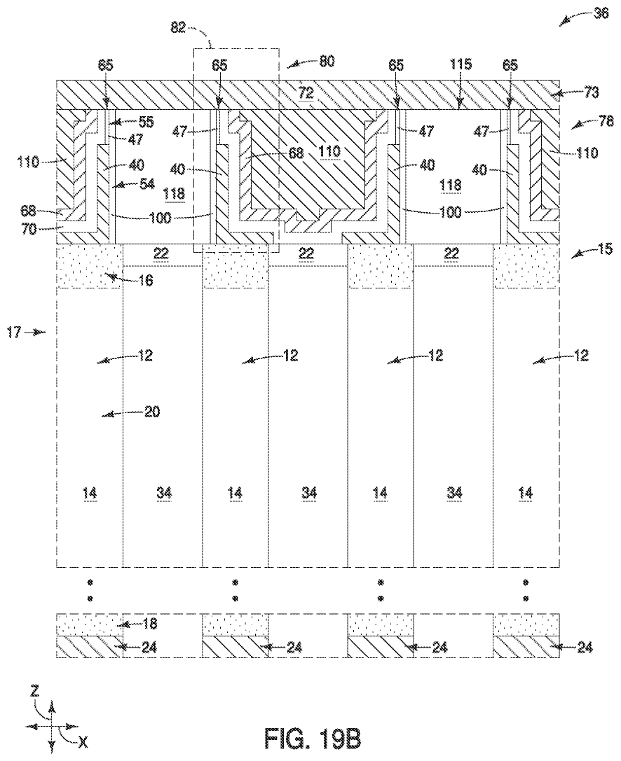

Referring to FIGS. 19-19B, additional top electrode material 72 is formed over the top electrode materials 68 and 110. The material 72 may be referred to as plate material. The material 72 may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.).

The material 72 may or may not comprise a same composition as one or both of the materials 68 and 110. In some embodiments, the materials 68 and 110 comprise, consist essentially of, or consist of titanium nitride, and the material 72 comprises, consists essentially of, or consists of tungsten.

The conductive materials 68, 110 and 72 together form a top electrode (or a plate electrode) 73.

The top electrode 73 is directly against the upper edges 65 of the leaker-device-structures 55. Accordingly, the leaker-device-structures 55 extend between the bottom electrodes 54 and the top electrode 73, and are directly against the bottom electrodes 54 and the top electrode 73.

The bottom electrodes 54, capacitor-insulative-material 70, and top electrode 73 together form capacitors 82 (one of which is labeled in each of FIGS. 19A and 19B). The capacitors are incorporated into memory cells 80 (one of which is labeled in each of FIGS. 19A and 19B), with the memory cells forming a memory array 78.

In some embodiments, the leaker-device-structures (leaker devices) 55 may be considered to be resistive interconnects coupling bottom electrodes 54 to the top electrode 73 within the individual capacitors 82, and may be utilized to drain excess charge from the bottom electrodes 54 to alleviate or prevent undesired charge build-up. If the leaker devices 55 are too leaky, then one or more memory cells 80 may experience cell-to-cell disturb. If the leaker devices 55 are not leaky (conductive) enough, then excess charge from the bottom electrodes 54 may not be adequately drained. Persons of ordinary skill in the art will recognize how to calculate the resistance needed for the leaker devices 55 for a given memory array. In some embodiments, the leaker devices 55 may have resistance within a range of from about 0.1 megaohms to about 5 megaohms. Factors such as separation between adjacent memory cells, physical dimensions of the memory cells, the amount of charge placed in the memory cells, a size of the memory array, a frequency of operations conducted by the memory array, etc., may be considered when making a determination of the resistance appropriate for the leaker devices 55.

The integrated assembly 36 of FIGS. 19-19B may be considered to correspond to a portion of the memory array (memory device) 78. Such memory array includes the memory cells 80 which each include a capacitor 82. The capacitors each include one of the bottom electrodes 54; and includes regions of the insulative material 70 and the top electrode (plate electrode) 73.

The individual memory cells 80 each include an access transistor 84 coupled with the capacitor 82 (one of the access transistors 84 is diagrammatically indicated in FIG. 19A). Each of the access transistors 84 includes a pillar 12 and a region of a transistor gate 26 adjacent such pillar.

Each of the memory cells 80 is uniquely addressed by one of the word lines 25 in combination with one of the digit lines 24. In some embodiments, the memory cells 80 may be considered to be substantially identical to one another, and to be representative of a large number of substantially identical memory cells which may be formed across the memory array 78. For instance, the memory array may comprise hundreds, thousands, hundreds of thousands, millions, hundreds of millions, etc., of the memory cells. The word lines 25 may be representative of a large number of substantially identical word lines that may extend along rows of the memory array, and the digit lines 24 may be representative of a large number of substantially identical digit lines that may extend along columns of the memory array. The term “substantially identical” means identical to within reasonable tolerances of fabrication and measurement.

In some embodiments, the capacitors 82 may be ferroelectric capacitors comprising ferroelectric-insulative-material 70. Accordingly, the memory array 78 may comprise FeRAM.

Some embodiments include recognition that it may be advantageous to sub-divide the top electrode 73 into multiple plates. Voltage to the individual plates may be independently controlled, which may enable the electric field across the material 70 to be tailored within specific regions of the memory array 78 during memory operations e.g., READ/WRITE operations). Such may enable charge/discharge rates of the capacitors 82 to be increased, which may improve operational speeds associated with memory cells 80 of the memory array 78. It may be particularly advantageous for the top electrode material to be subdivided with slits extending along the column direction (i.e., the y-axis direction of the figures).

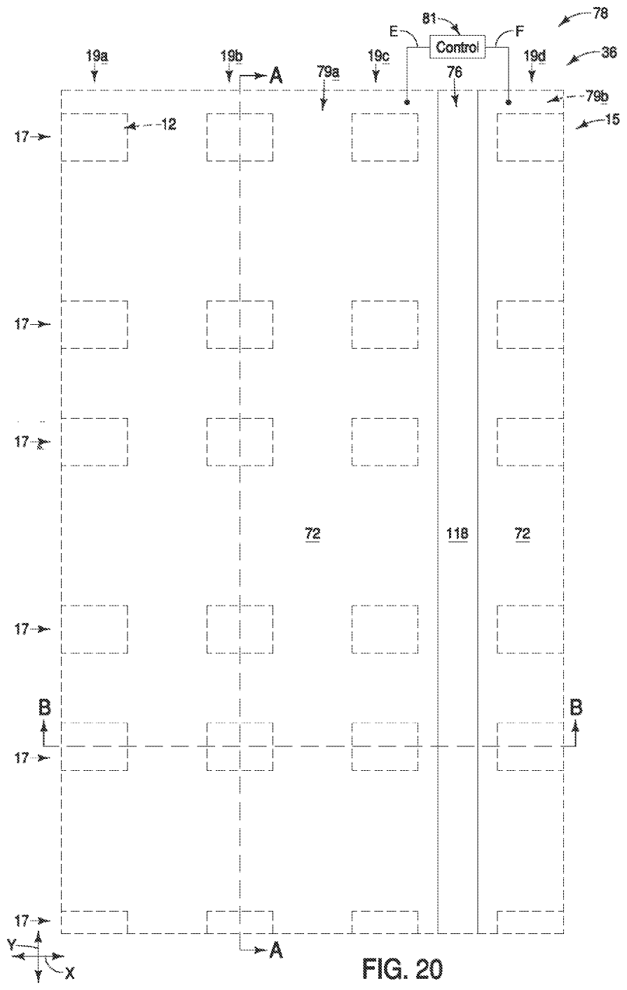

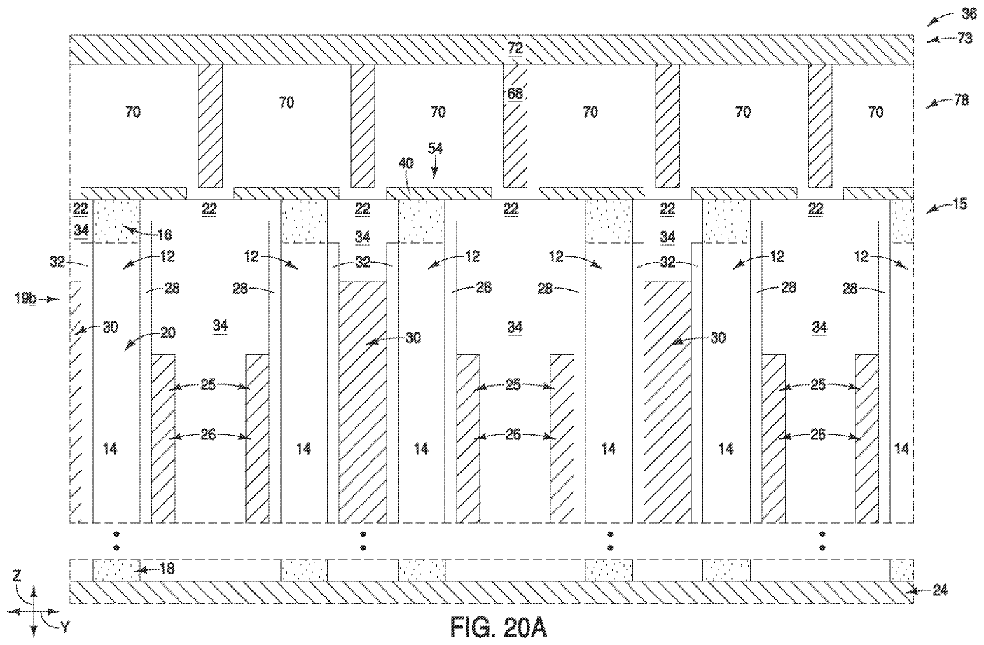

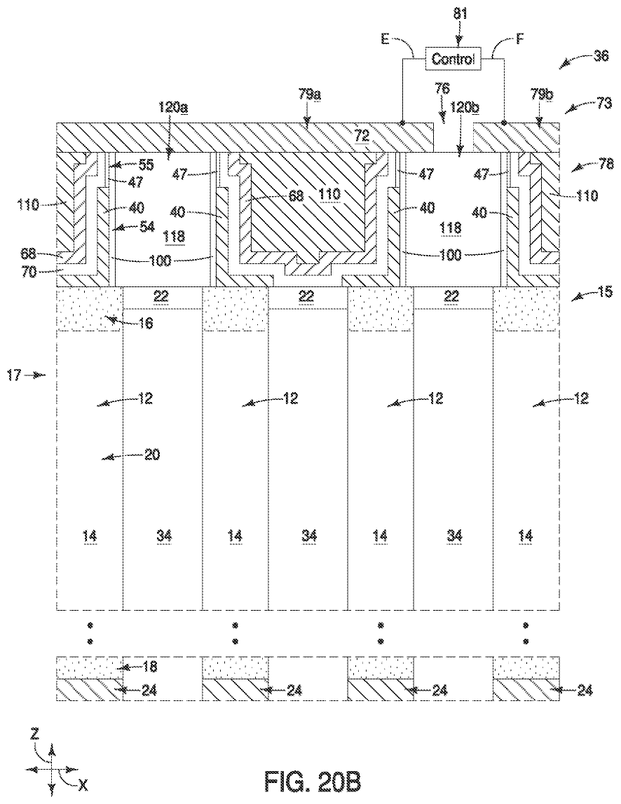

FIGS. 20-20B show the assembly 36 after a slit 76 is formed to extend through the top-electrode-material 72 (i.e., through the top electrode 73). In the shown embodiment, the slit 76 stops at the sacrificial material 118 of the insulative structure 120b. In other embodiments, the slits may penetrate into (or even through) the sacrificial material 118. The slit 76 may be patterned with any suitable processing. For instance, a photoresist mask (not shown) may be used to define the location of the slit, one or more etches may be used to etch through the material 72 and form the slit in such location, and then the mask may be removed to leave the configuration of FIGS. 15-15B.

The illustrated slit 76 extends along the column direction (i.e., the illustrated y-axis direction) and is directly over the linear structure 120b. Although one slit 76 is shown, there may be additional slits formed in other embodiments.

The slit 76 subdivides the top electrode 73 into plate structures (e.g., plates, plate lines) 79a and 79b. Although two of the plates 79 are formed in the shown embodiment, in other embodiments there may be a different number of plates formed depending on the number of the slits 76 formed. Generally, there will be at least two of the plates 79 formed utilizing the slit(s) 76.

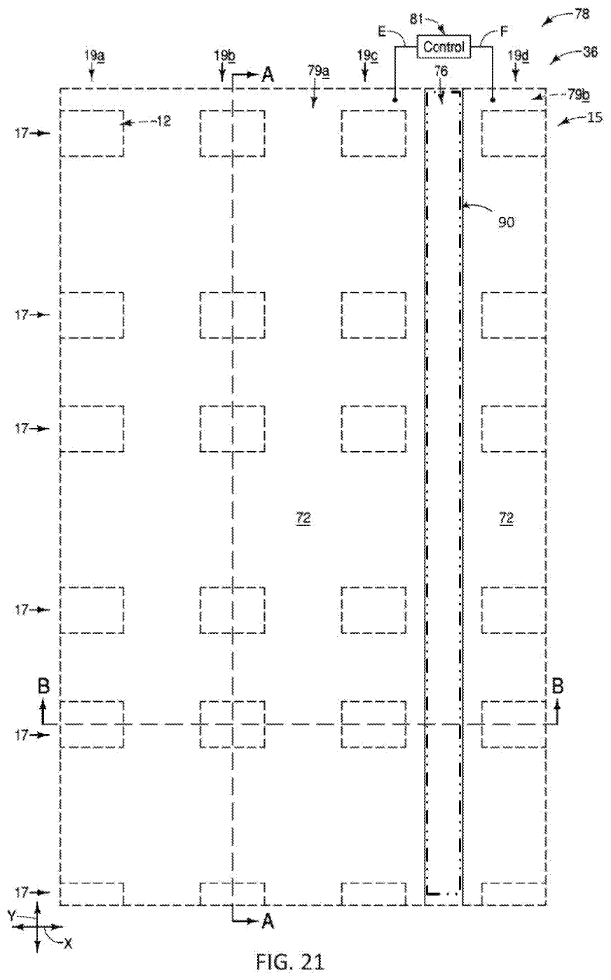

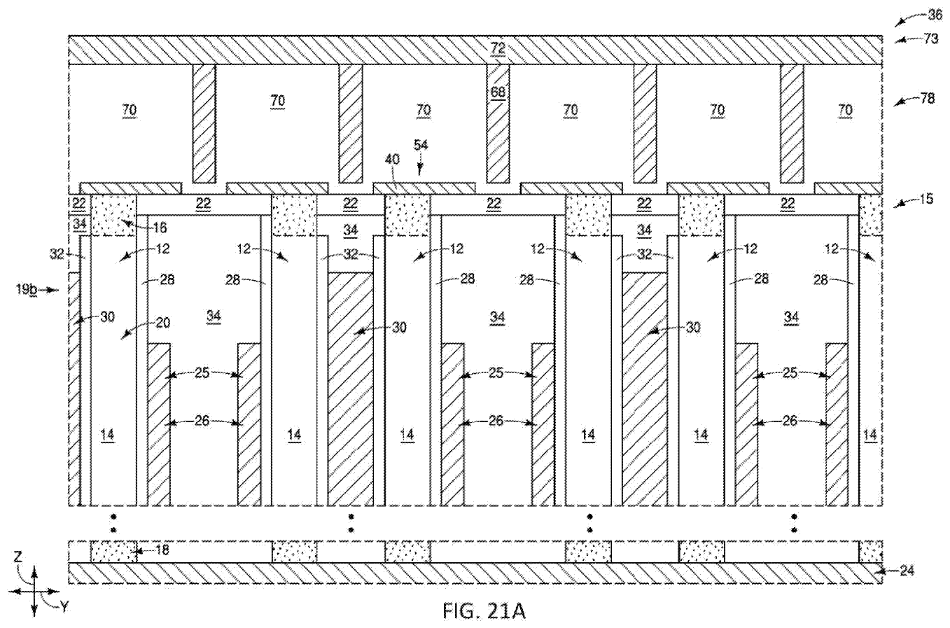

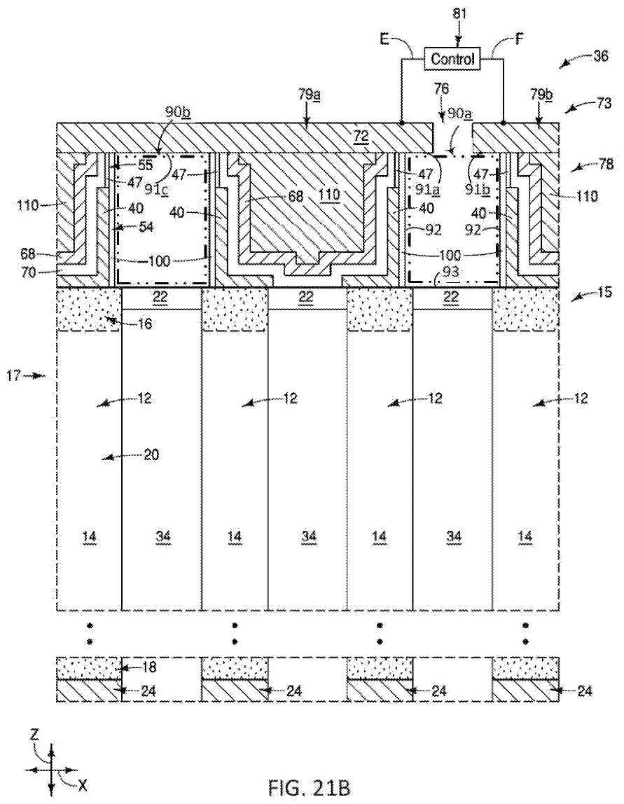

FIGS. 21-21B show the assembly 36 after one or more voids 90 are formed by removing the material 118. For example, removing the linear structures 120 may leave behind empty spaces (e.g., spaces without the material 118), which may expose portions of the assembly 36 (e.g., portions of the protective material 100, portions of the surface of the transistor array, portions of the top-electrode-material 72) that define the void 90a and the void 90b.

The material 118 may be removed using any suitable material removal process. For example, the material 118 may be removed using a wet etch process or a wet exhume process. In some cases, the material removal process may include depositing a chemical agent to contact the material 118, such as depositing the chemical agent through the slit 76, The chemical agent may then exhume the material 118. which may form the void 90a and the void 90b.

In some cases, the process to remove the material 118 may be selective to the material 118. Accordingly, after removing the material 118, other materials of the assembly 36 may remain. For example, the protective material 100 of the liner structures, the material 22, the 72, or any combination thereof, may not be removed by the material removal process.

10291 The voids 90 may expose one or more surfaces of the assembly 36. For example, the void 90a may expose portions of the plate lines 79a and 79b, such as a portion of the lower surface 91a of the plate line 790 and a portion of the lower surface 91b of the plate line 79b. In some cases, a void 90 may expose a portion of a single plate line. For example, the void 90b may expose a portion of the lower surface 91c of the plate line 79a.

The voids 90 may further expose portions of the protective material 100 and of the transistor array. For example, the void 90a may expose sidewalls 92 of the liner structures. For example, the void 90a may expose a sidewall 92a of a first liner structure (e.g., a sidewall opposite a second sidewall of the first liner structure in contact with the bottom-electrode-material 40) and a sidewall 92b of a second liner structure (e.g., a sidewall opposite a second sidewall of the second liner structure in contact with the bottom-electrode-material 40). The void 90a may further expose a surface of the transistor array, which may include at least a portion of a surface 93 of the material 22. In some cases, the void 90a may further expose at least portion of a surface 94 of a source/drain region 16 (e.g., the contacts of the transistor array).

The voids 90a and 90h may reduce a capacitance between bottom electrodes 54 in adjacent columns. (e.g., bottom electrodes 54 on opposite sides of the void 90a or the void 90b). For example, the voids 90a and 90b may include a substance, which may be fluid, such as air. This substance (e.g., fluid such as air) may have a relatively low dielectric constant compared with the material 118, and so may reduce the capacitance between the bottom electrodes 54.

Control circuitry 81 (which may also be referred to as a control circuit) may be utilized to provide desired voltages to the plates 79 (i.e., to independently control voltages to the different plates 79).

The illustrated plates 79a and 79b may be at a different voltage relative to one another. Specifically, one of the plates may be at a first voltage, and another of the plates may be at a second voltage which is different than the first voltage. In the shown embodiment, the control circuity 81 provides voltages E and F to the separate plates 79a and 79b. If there are more than two of the plates 79, the control circuitry 81 may provide a different voltage to at least one of the plates relative to at least one other of the plates.

The memory array 78 of FIGS. 21-21B may have any suitable configuration. An example FeRAM array 78 is described schematically with reference to FIG. 21. The memory array includes a plurality of substantially identical memory cells 80, which each include a ferroelectric capacitor 82 and an access transistor 84. Word lines 25 extend along rows of the memory array, and digit lines 24 extend along columns of the memory array. Each of the memory cells is uniquely addressed utilizing a combination of a word line and a digit line. The word lines extend to driver circuitry (Word line Driver Circuitry) 130, and the digit lines 24 extend to detecting (sensing) circuitry (Sense Amplifier Circuitry) 140. The top electrodes of the capacitors 82 are shown coupled with plate structures 79. and the plate structures are shown to be coupled with the control circuitry 81.

At least some of the circuitry 130, 140 and 81 may be directly under the memory array 78. One or more of the circuitries 130, 140 and 81 may include CMOS, and accordingly some embodiments may include CMOS-under-array architecture.

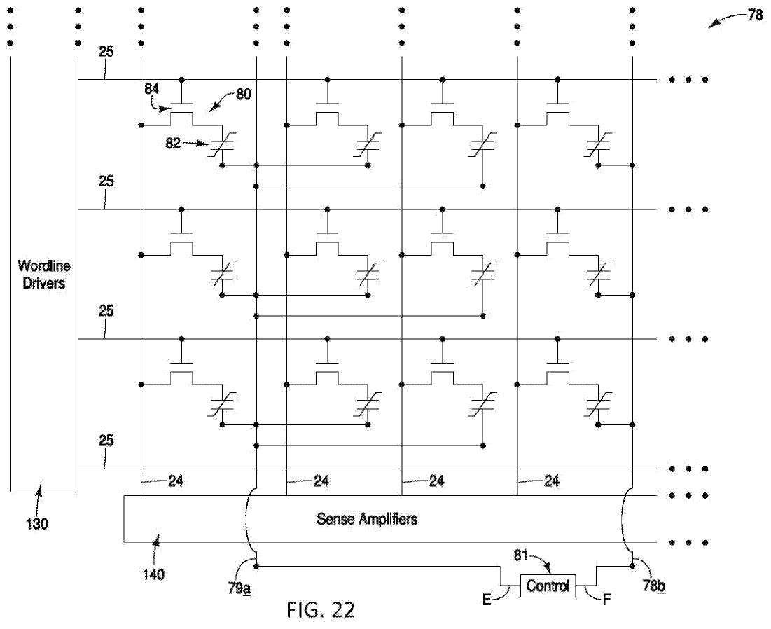

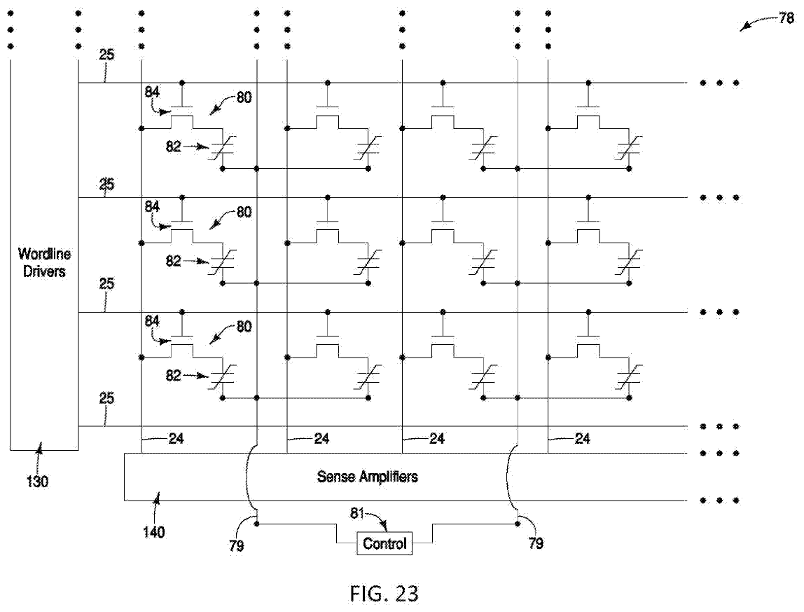

FIGS. 22 and 23 show an embodiment in which a plate structure is shared by three columns of memory cells. In other embodiments, a different number of memory cells may share a plate structure, depending on the number of slits 76 that are formed. For instance. FIG. 23 schematically illustrates a region of the memory array 78 similar to that of FIG. 22, except that two columns memory cells 80 share each of the plate structures 79.

FIG. 24 shows a flowchart illustrating a method 2400 that supports memory structures with voids in accordance with examples as disclosed herein. The operations of method 2400 may be implemented by a manufacturing system or its components as described herein. For example, the operations of method 2400 may be performed by a manufacturing system as described with reference to FIGS. 1 through 23. In some examples, a manufacturing system may execute a set of instructions to control the functional elements of the device to perform the described functions. Additionally, or alternatively, the manufacturing system may perform aspects of the described functions using special-purpose hardware.

At 2405, the method may include forming a first sacrificial structure over a transistor array, the sacrificial structure extending in a first direction. The operations of 2405 may be performed in accordance with examples as disclosed herein.

At 2410, the method may include forming a first set of electrodes on a first sidewall of the sacrificial structure and a second set of electrodes on a second sidewall of the first sacrificial structure. The operations of 2410 may be performed in accordance with examples as disclosed herein.

At 2415, the method may include forming a ferroelectric material on a respective sidewall of each electrode of the first set of electrodes and on a respective sidewall of each electrode of the second set of electrodes. The operations of 2415 may be performed in accordance with examples as disclosed herein.

At 2420, the method may include removing the first sacrificial structure based at least in part on forming the ferroelectric material. The operations of 2420 may be performed in accordance with examples as disclosed herein.

At 2425, the method may include removing a portion of the ferroelectric material between a first electrode and a second electrode of the first set of electrodes based at least in part on removing the first sacrificial structure. The operations of 2425 may be performed in accordance with examples as disclosed herein.

At 2430, the method may include forming second sacrificial structure between the first set of electrodes and the second set of electrodes, the second sacrificial structure extending in the first direction. The operations of 2430 may be performed in accordance with examples as disclosed herein.

At 2435, the method may include forming a plate line over the ferroelectric material and the second sacrificial structure, the plate line extending in the first direction. The operations of 2435 may be performed in accordance with examples as disclosed herein.

At 2440, the method may include removing the second sacrificial structure to form a void based at least in part on forming the plate line, the void exposing a portion of a lower surface of the plate line. The operations of 2440 may be performed in accordance with examples as disclosed herein.

In some examples, an apparatus (e.g., a manufacturing system) as described herein may perform a method or methods, such as the method 2400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a first sacrificial structure over a transistor array, the sacrificial structure extending in a first direction; forming a first set of electrodes on a first sidewall of the sacrificial structure and a second set of electrodes on a second sidewall of the first sacrificial structure; forming a ferroelectric material on a respective sidewall of each electrode of the first set of electrodes and on a respective sidewall of each electrode of the second set of electrodes; removing the first sacrificial structure based at least in part on forming the ferroelectric material; removing a portion of the ferroelectric material between a first electrode and a second electrode of the first set of electrodes based at least in part on removing the first sacrificial structure; forming second sacrificial structure between the first set of electrodes and the second set of electrodes, the second sacrificial structure extending in the first direction, forming a plate line over the ferroelectric material and the second sacrificial structure, the plate line extending in the first direction; and removing the second sacrificial structure to form a void based at least in part on forming the plate line, the void exposing a portion of a lower surface of the plate line.

Aspect 2: The method or apparatus of aspect 13, further including operations, features, circuitry, logic, means, or instructions, or any combination thereof for forming a first liner structure on the first sidewall of the first sacrificial structure, where forming the first set of electrodes is based at least in part on forming the first liner structure and forming a second liner structure on the second sidewall of the first sacrificial structure, where forming the second set of electrodes is based at least in part on forming the second liner structure.

Aspect 3: The method or apparatus of aspect 14, where forming the first set of electrodes includes operations, features, circuitry, logic, means, or instructions, or any combination thereof for depositing a layer of conductive material on a first sidewall of the first liner structure and on a surface of the transistor array and etching the layer of conductive material to form the first set of electrodes, the etching exposing portions of the first sidewall of the first liner structure and exposing a portion of the surface of the transistor array.

Aspect 4: The method or apparatus of aspect 15, where the void exposes a second sidewall of the first liner structure.

Aspect 5: The method or apparatus of any of aspects 15 through 16, where each electrode of the first set of electrodes includes operations, features, circuitry, logic, means, or instructions, or any combination thereof for a respective first segment on the first sidewall of the first liner structure; and a respective second segment on the surface of the transistor array.

Aspect 6: The method or apparatus of any of aspects 13 through 17, where the void exposes a portion of a lower surface of a second plate line different than the plate line.

Aspect 7: The method or apparatus of any of aspects 13 through 18, where the second sacrificial structure is removed using a wet exhume process.

Aspect 8: The method or apparatus of any of aspects 13 through 19, where forming the plate line includes operations, features, circuitry, logic, means, or instructions, or any combination thereof for depositing a conductive material over the ferroelectric material and etching the conductive material to form the plate line, where the etching exposes respective a portion of an upper surface of the second sacrificial structure.

Aspect 9: The method or apparatus of any of aspects 13 through 20, where forming the first sacrificial structure includes operations, features, circuitry, logic, means, or instructions, or any combination thereof for depositing a layer of oxide material on a surface of the transistor array and etching the layer of oxide material to form the sacrificial structure, where the first sacrificial structure includes the oxide material.

Aspect 10: The method or apparatus of aspect 21, where etching the layer of oxide forms a set of trenches extending in the first direction, each trench exposing a respective portion of the surface of the transistor array.

Aspect 11: The method or apparatus of any of aspects 13 through 22, where the void exposes a portion of a surface of the transistor array.

Aspect 12: The method or apparatus of any of aspects 13 through 23, where the transistor array includes a set of transistors arranged in one or more columns extending in the first direction and one or more rows extending in a second direction, the one or more columns including a first column of a first subset of first transistors of the set of transistors, each first transistor including a respective contact coupled with an electrode of the first set of electrodes, and a second column of a second subset of second transistors of the set of transistors, each second transistor including a respective contact coupled with an electrode of the second set of electrodes.

FIG. 25 shows a flowchart illustrating a method 2500 that supports memory structures with voids in accordance with examples as disclosed herein. The operations of method 2500 may be implemented by a manufacturing system or one or more controllers associated with a manufacturing system. in some examples, one or more controllers may execute a set of instructions to control one or more functional elements of the manufacturing system to perform the described functions. Additionally, or alternatively, one or more controllers may perform aspects of the described functions using special-purpose hardware.

At 2505, the method may include forming a sacrificial structure over a transistor array, the sacrificial structure extending in a first direction. The operations of 2505 may be performed in accordance with examples as disclosed herein.

At 2510, the method may include forming a first set of electrodes on a first sidewall of the sacrificial structure and a second set of electrodes on a second sidewall of the sacrificial structure. The operations of 2510 may be performed in accordance with examples as disclosed herein.

At 2515, the method may include forming a ferroelectric material on a respective sidewall of each electrode of the first set of electrodes and on a respective sidewall of each electrode of the second set of electrodes. The operations of 2515 may be performed in accordance with examples as disclosed herein.

At 2520, the method may include forming a plate line over the ferroelectric material, the plate line extending in the first direction. The operations of 2520 may be performed in accordance with examples as disclosed herein.

At 2525, the method may include removing the sacrificial structure to form a void based at least in part on forming the plate line, the void exposing a portion of a lower surface of the plate line. The operations of 2525 may be performed in accordance with examples as disclosed herein.

In some examples, an apparatus (e.g., a manufacturing system) as described herein may perform a method or methods, such as the method 2500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 13: A method or apparatus including operations, features, circuitry, logic, means, or instructions, or any combination thereof for forming a sacrificial structure over a transistor array, the sacrificial structure extending in a first direction; forming a first set of electrodes on a first sidewall of the sacrificial structure and a second set of electrodes on a second sidewall of the sacrificial structure; forming a ferroelectric material on a respective sidewall of each electrode of the first set of electrodes and on a respective sidewall of each electrode of the second set of electrodes; forming a plate line over the ferroelectric material, the plate line extending in the first direction; and removing the sacrificial structure to form a void based at least in part on forming the plate line, the void exposing a portion of a lower surface of the plate line.

Aspect 14: The method or apparatus of aspect 13, further including operations, features, circuitry, logic, means, or instructions, or any combination thereof for forming a first liner structure on the first sidewall of the sacrificial structure, where forming the first set of electrodes is based at least in part on forming the first liner structure and forming a second liner structure on the second sidewall of the sacrificial structure, where forming the second set of electrodes is based at least in part on forming the second liner structure.

Aspect 15: The method or apparatus of aspect 14, where forming the first set of electrodes includes operations, features, circuitry, logic, means, or instructions, or any combination thereof for depositing a layer of conductive material on a first sidewall of the first liner structure and on a surface of the transistor array and etching the layer of conductive material to form the first set of electrodes, the etching exposing portions of the first sidewall of the first liner structure and exposing a portion of the surface of the transistor array.

Aspect 16: The method or apparatus of aspect 15, where the void exposes a second sidewall of the first liner structure.

Aspect 17: The method or apparatus of any of aspects 15 through 16, where each electrode of the first set of electrodes includes operations, features, circuitry, logic, means, or instructions, or any combination thereof for a respective first segment on the first sidewall of the first liner structure; and a respective second segment on the surface of the transistor array.

Aspect 18: The method or apparatus of any of aspects 13 through 17, where the void exposes a portion of a lower surface of a second plate line different than the plate line.

Aspect 19: The method or apparatus of any of aspects 13 through 18, where the sacrificial structure is removed using a wet exhume process.

Aspect 20: The method or apparatus of any of aspects 13 through 19, where forming the plate line includes operations, features, circuitry, logic, means, or instructions, or any combination thereof for depositing a conductive material over the ferroelectric material and etching the conductive material to form the plate line, where the etching exposes respective a portion of an upper surface of the sacrificial structure.

Aspect 21: The method or apparatus of any of aspects 13 through 20, where forming the sacrificial structure includes operations, features, circuitry, logic, means, or instructions, or any combination thereof for depositing a layer of oxide material on a surface of the transistor array and etching the layer of oxide material to form the sacrificial structure, where the sacrificial structure includes the oxide material.

Aspect 22: The method or apparatus of aspect 21, where etching the layer of oxide forms a set of trenches extending in the first direction, each trench exposing a respective portion of the surface of the transistor array.

Aspect 23: The method or apparatus of any of aspects 13 through 22, where the void exposes a portion of a surface of the transistor array.

Aspect 24: The method or apparatus of any of aspects 13 through 23, where the transistor array includes a set of transistors arranged in one or more columns extending in the first direction and one or more rows extending in a second direction, the one or more columns including a first column of a first subset of first transistors of the set of transistors, each first transistor including a respective contact coupled with an electrode of the first set of electrodes, and a second column of a second subset of second transistors of the set of transistors, each second transistor including a respective contact coupled with an electrode of the second set of electrodes.

It should be noted that the methods described herein are possible implementations, arid that the operations and the steps may be rearranged or otherwise modified and that other implementations are possible. Furthermore, portions from two or more of the methods may be combined.

An apparatus is described. The following provides an overview of aspects of the apparatus as described herein:

Aspect 25: An apparatus, including: a first plurality of memory cells on a first sidewall of a first liner structure extending in a first direction over a transistor array and coupled with a first digit line; a second plurality of memory cells on a first sidewall of a second liner structure extending in the first direction over the transistor array and coupled with a second digit line; and a void between the first liner structure and the second liner structure, the void exposing a second sidewall of the first liner structure and a second sidewall of the second liner structure.

Aspect 26: The apparatus of aspect 25, where: a first memory cell of the first plurality of memory cells includes a first electrode having a first sidewall on the first liner structure and a second sidewall coupled with a first ferroelectric layer; and a second memory cell of the second plurality of memory cells includes a second electrode having a third sidewall on the second liner structure and a fourth sidewall coupled with a second ferroelectric layer.

Aspect 27: The apparatus of aspect 26. where a first plate line extending in the first direction is coupled with the first ferroelectric layer and a second plate line extending in the first direction is coupled with the second ferroelectric layer.

Aspect 28: The apparatus of any of aspects 25 through 27, further including: a third plurality of memory cells on a sidewall of a third liner structure extending in the first direction over the transistor array, the third plurality of memory cells and the first plurality of memory cells coupled with a first plate line, where the third plurality of memory cells is further coupled with a third digit line.

Aspect 29: The apparatus of aspect 28, further including: a fourth plurality of memory cells on a sidewall of a fourth liner structure extending in the first direction over the transistor array, the fourth plurality of memory cells coupled with the first plate line, where the fourth plurality of memory cells is further coupled with a fourth digit line.

Aspect 30: The apparatus of aspect 29, further including: a second void between the third liner structure and the fourth liner structure, the second void exposing a second sidewall of the third liner structure and a second sidewall of the fourth liner structure.

Aspect 31: The apparatus of aspect 30, where the second void exposes a portion of a lower surface of the first plate line.

Aspect 32: The apparatus of any of aspects 28 through 31, where: a first memory , cell of the first plurality of memory cells includes a first electrode having a first sidewall the first liner structure and a second sidewall coupled with a first ferroelectric layer, and a second memory cell of the third plurality of memory cells includes a second electrode having a third sidewall on the third liner structure and a fourth sidewall coupled with a second ferroelectric layer, where the first plate line is coupled with the first ferroelectric layer and the second ferroelectric layer.

Aspect 33: The apparatus of aspect 32, where the first plate line extends between the second sidewall and the fourth sidewall.

Aspect 34: The apparatus of any of aspects 25 through 33, where the void exposes at least a portion of a lower surface of a first plate line coupled with the first plurality of memory cells and a portion of a lower surface of a second plate line coupled with the second plurality of memory cells.

Aspect 35: The apparatus of any of aspects 25 through 34, where the void exposes at least a portion of a surface of the transistor array.

Aspect 36: The apparatus of any of aspects 25 through 35, where the transistor array includes: a set of transistors arranged in one or more columns extending in the first direction and one or more rows extending in a second direction, the set of transistors including a first column of transistors having contacts coupled with the first plurality of memory cells and a second column of transistors having contacts coupled with the second plurality of memory cells.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be fowled on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the EFT may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

Unless specified otherwise, the various materials, substances, compositions, etc. described herein may be formed with any suitable methodologies, either now known or vet to be developed, including, for example, atomic layer deposition (ALD), chemical vapor deposition (CVD), physical vapor deposition (PVD), etc.

The terms “dielectric” and “insulative” may be utilized to describe materials having insulative electrical properties. The terms are considered synonymous in this disclosure. The utilization of the term “dielectric” in some instances, and the term “insulative” (or “electrically insulative”) in other instances, may be to provide language variation within this disclosure to simplify antecedent basis within the claims that follow, and is not utilized to indicate any significant chemical or electrical differences.

The particular orientation of the various embodiments in the drawings is for illustrative purposes only, and the embodiments may be rotated relative to the shown orientations in some applications. The descriptions provided herein, and the claims that follow, pertain to any structures that have the described relationships between various features, regardless of whether the structures are in the particular orientation of the drawings, or are rotated relative to such orientation.

The cross-sectional views of the accompanying illustrations only show features within the planes of the cross-sections, and do not show materials behind the planes of the cross-sections, unless indicated otherwise, in order to simplify the drawings.

When a structure is referred to above as being “on”, “adjacent” or “against” another structure, it can be directly on the other structure or intervening structures may also be present. In contrast, when a structure is referred to as being “directly on”, “directly adjacent” or “directly against” another structure, there are no intervening structures present. The terms “directly under”, “directly over”, etc., do not indicate direct physical contact (unless expressly stated otherwise), but instead indicate upright alignment.

Structures (e.g., layers, materials, etc.) may be referred to as “extending vertically” to indicate that the structures generally extend away (e.g., upwardly) from an underlying base (e.g., substrate). The vertically-extending structures may extend substantially orthogonally relative to an upper surface of the underlying base, or not.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a first plurality of memory cells on a first sidewall of a first liner structure extending in a first direction over a transistor array and coupled with a first digit line;
a second plurality of memory cells on a first sidewall of a second liner structure extending in the first direction over the transistor array and coupled with a second digit line; and
a void between the first liner structure and the second liner structure, the void exposing a second sidewall of the first liner structure and a second sidewall of the second liner structure.

2. The apparatus of claim 1, wherein:
a first memory cell of the first plurality of memory cells comprises a first electrode having a first sidewall on the first liner structure and a second sidewall coupled with a first ferroelectric layer; and
a second memory cell of the second plurality of memory cells comprises a second electrode having a third sidewall on the second liner structure and a fourth sidewall coupled with a second ferroelectric layer.

3. The apparatus of claim 2, wherein a first plate line extending in the first direction is coupled with the first ferroelectric layer and a second plate line extending in the first direction is coupled with the second ferroelectric layer.

4. The apparatus of claim 1, further comprising:
a third plurality of memory cells on a sidewall of a third liner structure extending in the first direction over the transistor array, the third plurality of memory cells and the first plurality of memory cells coupled with a first plate line, wherein the third plurality of memory cells is further coupled with a third digit line.

5. The apparatus of claim 4, further comprising:
a fourth plurality of memory cells on a sidewall of a fourth liner structure extending in the first direction over the transistor array, the fourth plurality of memory cells coupled with the first plate line, wherein the fourth plurality of memory cells is further coupled with a fourth digit line.

6. The apparatus of claim 5, further comprising:
a second void between the third liner structure and the fourth liner structure, the second void exposing a second sidewall of the third liner structure and a second sidewall of the fourth liner structure.

7. The apparatus of claim 6, wherein the second void exposes a portion of a lower surface of the first plate line.

8. The apparatus of claim 4, wherein:
a first memory cell of the first plurality of memory cells comprises a first electrode having a first sidewall on the first liner structure and a second sidewall coupled with a first ferroelectric layer; and
a second memory cell of the third plurality of memory cells comprises a second electrode having a third sidewall on the third liner structure and a fourth sidewall coupled with a second ferroelectric layer, wherein the first plate line is coupled with the first ferroelectric layer and the second ferroelectric layer.

9. The apparatus of claim 8, wherein the first plate line extends between the second sidewall and the fourth sidewall.

10. The apparatus of claim 1, wherein the void exposes at least a portion of a lower surface of a first plate line coupled with the first plurality of memory cells and a portion of a lower surface of a second plate line coupled with the second plurality of memory cells.

11. The apparatus of claim 1, wherein the void exposes at east a portion of a surface of the transistor array.

12. The apparatus of claim 1, wherein the transistor array comprises:
a set of transistors arranged in one or more columns extending in the first direction and one or more rows extending in a second direction, the set of transistors comprising a first column of transistors having contacts coupled with the first plurality of memory cells and a second column of transistors having contacts coupled with the second plurality of memory cells.

13. A method, comprising:
forming a first set of electrodes on a transistor array and a second set of electrodes on the transistor array;
forming a ferroelectric material on a respective sidewall of each electrode of the first set of electrodes and on a respective sidewall of each electrode of the second set of electrodes;
forming a first sacrificial structure between the first set of electrodes and the second set of electrodes, the first sacrificial structure extending in a first direction;
forming a plate line over the ferroelectric material and the first sacrificial structure, the plate line extending in the first direction; and
removing the first sacrificial structure to form a void based at least in part on forming the plate line, the void exposing a portion of a lower surface of the plate line.

14. The method of claim 13, further comprising:
forming a second sacrificial structure over the transistor array, the second sacrificial structure extending in a first direction, wherein the first set of electrodes are formed on a first sidewall of the second sacrificial structure and the second set of electrodes are formed on a second sidewall of the second sacrificial structure; and
removing the second sacrificial structure based at least in part on forming the ferroelectric material.

15. The method of claim 14, further comprising:
forming a first liner structure on the first sidewall of the second sacrificial structure, wherein forming the first set of electrodes is based at least in part on forming the first liner structure; and
forming a second liner structure on the second sidewall of the second sacrificial structure, wherein forming the second set of electrodes is based at least in part on forming the second liner structure.

16. The method of claim 15, wherein forming the first set of electrodes comprises:
depositing a layer of conductive material on a first sidewall of the first liner structure and on a surface of the transistor array; and
etching the layer of conductive material to form the first set of electrodes, the etching exposing portions of the first sidewall of the first liner structure and exposing a portion of the surface of the transistor array.

17. The method of claim 14, wherein forming the first sacrificial structure comprises:
depositing a layer of oxide material on a surface of the transistor array; and
etching the layer of oxide material to form the first sacrificial structure, wherein the first sacrificial structure comprises the oxide material.

18. The method of claim 13, wherein forming the plate line comprises:
depositing a conductive material over the ferroelectric material; and
etching the conductive material to form the plate line, wherein the etching exposes respective a portion of an upper surface of the first sacrificial structure.

19. A method, comprising:
forming a sacrificial structure over a transistor array, the sacrificial structure extending in a first direction;
forming a first set of electrodes on a first sidewall of the sacrificial structure and a second set of electrodes on a second sidewall of the sacrificial structure;
forming a ferroelectric material on a respective sidewall of each electrode of the first set of electrodes and on a respective sidewall of each electrode of the second set of electrodes;
forming a plate line over the ferroelectric material, the plate line extending in the first direction; and
removing the sacrificial structure to form a void based at least in part on forming the plate line, the void exposing a portion of a lower surface of the plate line.

20. The method of claim 19, further comprising:
forming a first liner structure on the first sidewall of the sacrificial structure, wherein forming the first set of electrodes is based at least in part on forming the first liner structure; and
forming a second liner structure on the second sidewall of the sacrificial structure, wherein forming the second set of electrodes is based at least in part on forming the second liner structure.
